(19) United States
(12) Patent Application Publication
(10) Pub. No.: US 2026/0188222 A1
(43) Pub. Date: Jul. 2, 2026

(54) DISPLAY DEVICE AND ELECTRONIC DEVICE

(71) Applicant: Samsung Display Co., Ltd., Yongin-si (KR)

(72) Inventors: BORAM CHOI, Yongin-si (KR); GYEONG-UB MOON, Yongin-si (KR); SEUNGHYUN MOON, Yongin-si (KR); KANGBIN JO, Yongin-si (KR); GOEUN CHA, Yongin-si (KR)

(21) Appl. No.: 19/371,859

(22) Filed: Oct. 28, 2025

(30) Foreign Application Priority Data
Dec. 31, 2024 (KR) 10-2024-0202584

(51) Int. Cl. G09G 3/3233; G06V 40/13; G09G 3/3266

(52) U.S. Cl. CPC G09G 3/3233; G09G 3/3266; G06V 40/1318; G09G 2300/0439; G09G 2300/0819; G09G 2300/0842; G09G 2300/0861; G09G 2310/08; G09G 2354/00; G09G 2360/14

(57) ABSTRACT

A display device includes: a base layer; a circuit layer on the base layer; and an element layer on the circuit layer and comprising light emitting elements and light receiving elements arranged in a display area, wherein the circuit layer comprises pixel circuits connected to the light emitting elements and sensor circuits connected to the light receiving elements, each of the pixel circuits and the sensor circuits are configured to receive one of scan signals sequentially activated, and a first transition time point of a first scan signal applied to a first pixel circuit arranged in a first circuit row among the pixel circuits is different from a second transition time point of a second scan signal applied to a first sensor circuit arranged in the first circuit row among the sensor circuits.

### CROSS-REFERENCE TO RELATED APPLICATION

The present application claims priority to and the benefit of Korean Patent Application No. 10-2024-0202584, filed on Dec. 31, 2024, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of Related Art

Display devices provide a variety of functions to organically interact with users, such as displaying images to provide information or detecting user input. Some display devices may incorporate features for detecting user's biometric information.

As biometric information recognition methods, a capacitive method that detects a variation in capacitance formed between electrodes, an optical method that detects an incident light using an optical sensor, an ultrasonic method that detects vibrations using a piezoelectric material, or the like may be used.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device including the same. For example, aspects of some embodiments of the present disclosure relate to a display device with a biometric information recognition function and an electronic device including the display device.

Aspects of some embodiments of the present disclosure include a display device with a relatively improved biometric information recognition function and an electronic device including the display device.

According to some embodiments of the present disclosure, a display device includes a base layer, a circuit layer on the base layer, and an element layer on the circuit layer and including light emitting elements and light receiving elements, which are arranged in a display area. According to some embodiments, the circuit layer includes pixel circuits connected to the light emitting elements and sensor circuits connected to the light receiving elements, each of the pixel circuits and the sensor circuits receives one of scan signals sequentially activated, and a first transition time point of a first scan signal applied to a first pixel circuit arranged in a first circuit row among the pixel circuits is different from a second transition time point of a second scan signal applied to a first sensor circuit arranged in the first circuit row among the sensor circuits.

According to some embodiments, a second pixel circuit arranged in a (k+1)th circuit row among the pixel circuits receives the second scan signal, a second sensor circuit arranged in the (k+1)th circuit row among the sensor circuits receives the first scan signal, and the k is an integer greater than or equal to 2.

According to some embodiments, the display device further includes pixel circuits arranged in k−1 circuit rows between the first pixel circuit and the second pixel circuit.

According to some embodiments, an activation period of the first scan signal does not overlap an activation period of the second scan signal.

According to some embodiments, an activation period of the first scan signal partially overlaps an activation period of the second scan signal.

According to some embodiments, the first transition time point of the first scan signal includes a first start time point and a first end time point, the second transition time point of the second scan signal includes a second start time point and a second end time point, the second start time point is different from the first start time point and the first end time point, and the second end time point is different from the first start time point and the first end time point.

According to some embodiments, the first pixel circuit includes a driving transistor connected between a corresponding light emitting element among the light emitting elements and a first power line, and a switching transistor connected to the driving transistor and receiving a data voltage and the first scan signal.

According to some embodiments, the first sensor circuit includes a reset transistor connected between a corresponding light receiving element among the light receiving elements and a reset voltage line, an amplification transistor connected to the reset transistor and receiving a sensing driving voltage, and an output transistor connected between the amplification transistor and a read-out line and receiving the second scan signal.

According to some embodiments of the present disclosure, a display device includes a base layer, a circuit layer on the base layer, and an element layer on the circuit layer and including light emitting elements and light receiving elements, which are arranged in a display area. According to some embodiments, the circuit layer includes pixel circuits connected to the light emitting elements and sensor circuits connected to the light receiving elements, each of the pixel circuits and the sensor circuits receives one of scan signals sequentially activated, a first scan signal is applied to a first pixel circuit arranged in a first circuit row among the pixel circuits, a first delay scan signal delayed from the first scan signal is applied to a first sensor circuit arranged in the first circuit row among the sensor circuits, and a transition time point of the first scan signal is different from a transition time point of the first delay scan signal.

According to some embodiments, an activation period of the first scan signal partially overlaps an activation period of the first delay scan signal.

According to some embodiments, the transition time point of the first scan signal includes a first start time point and a first end time point, the transition time point of the first delay scan signal includes a second start time point and a second end time point, the second start time point is different from the first start time point and the first end time point, and the second end time point is different from the first start time point and the first end time point.

According to some embodiments, the display device further includes a signal delay part that receives the first scan signal and outputs the first delay scan signal to the first sensor circuit.

According to some embodiments, the first pixel circuit includes a driving transistor connected between a corresponding light emitting element among the light emitting elements and a first power line and a switching transistor connected to the driving transistor and receiving a data voltage and the first scan signal.

According to some embodiments, the first sensor circuit includes a reset transistor connected between a corresponding light receiving element among the light receiving elements and a reset voltage line, an amplification transistor connected to the reset transistor and receiving a sensing driving voltage, and an output transistor connected between the amplification transistor and a read-out line and receiving the first delay scan signal.

According to some embodiments, a second pixel circuit arranged in a second circuit row among the pixel circuits receives a second scan signal, a second sensor circuit arranged in the second circuit row among the sensor circuits receives a second delay scan signal delayed from the second scan signal, and a transition time point of the second scan signal is different from a transition time point of the second delay scan signal.

According to some embodiments, the transition time point of the first delay scan signal is different from the transition time point of the second scan signal.

According to some embodiments of the present disclosure include an electronic device including a display panel including pixels and sensors, a data driver applying a data voltage to the pixels, and a scan driver applying scan signals to the pixels and the sensors. According to some embodiments, the pixels include light emitting elements and pixel circuits connected to the light emitting elements, the sensors include light receiving elements and sensor circuits connected to the light receiving elements, and a first transition time point of a first scan signal applied to a first pixel circuit arranged in a first circuit row among the pixel circuits is different from a second transition time point of a second scan signal applied to a first sensor circuit arranged in the first circuit row among the sensor circuits.

According to some embodiments, a second pixel circuit arranged in a (k+1)th circuit row among the pixel circuits receives the second scan signal, and a second sensor circuit arranged in the (k+1)th circuit row among the sensor circuits receives the first scan signal. According to some embodiments, the k is an integer greater than or equal to 2.

According to some embodiments, the first pixel circuit includes a driving transistor connected between a corresponding light emitting element among the light emitting elements and a first power line and a switching transistor connected to the driving transistor and receiving the data voltage and the first scan signal.

According to some embodiments, the first sensor circuit includes a reset transistor connected between a corresponding light receiving element among the light receiving elements and a reset voltage line, an amplification transistor connected to the reset transistor and receiving a sensing driving voltage, and an output transistor connected between the amplification transistor and a read-out line and receiving the second scan signal.

According to some embodiments of the present disclosure, the switching transistor of the pixel circuit and the output transistor of the sensor circuit receive the write scan signal. According to some embodiments, the pixel circuit and the sensor circuit, which are adjacent to each other, receive different write scan signals, and the pixel circuit and the sensor circuit, which receive the same write scan signal, are physically spaced apart from each other. Accordingly, noises generated when the pixel circuit and the sensor circuit are arranged adjacent to each other may be eliminated or reduced, and thus, the sensing performance of the electronic device may be relatively improved.

### BRIEF DESCRIPTION OF THE DRAWINGS

FIG. 1 is a perspective view of an electronic device according to some embodiments of the present disclosure;

FIG. 2 is a cross-sectional view of a display device according to some embodiments of the present disclosure;

FIG. 3 is a block diagram of a display device according to some embodiments of the present disclosure;

FIG. 4 is a circuit diagram of a pixel and a sensor according to some embodiments of the present disclosure;

FIG. 5 is a waveform diagram illustrating an operation of the pixel and the sensor shown in FIG. 4;

FIG. 6 is a cross-sectional view of a pixel and a sensor of a display panel according to some embodiments of the present disclosure;

FIG. 7 is an enlarged plan view of a portion of a display panel according to some embodiments of the present disclosure;

FIG. 8 is a block diagram of a pixel circuit and a sensor circuit according to some embodiments of the present disclosure;

FIG. 9 is a timing diagram of scan signals shown in FIG. 8 according to some embodiments of the present disclosure;

FIG. 10 is a timing diagram of scan signals shown in FIG. 8 according to some embodiments of the present disclosure;

FIG. 11 is a block diagram of a pixel circuit and a sensor circuit according to some embodiments of the present disclosure;

FIG. 12 is a timing diagram of scan signals shown in FIG. 11;

FIG. 13 is a black diagram of a pixel circuit and a sensor circuit according to some embodiments of the present disclosure;

FIG. 14 is a timing diagram of scan signals shown in FIG. 13; and

FIG. 15 is a block diagram of an electronic device according to some embodiments of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to accompanying drawings.

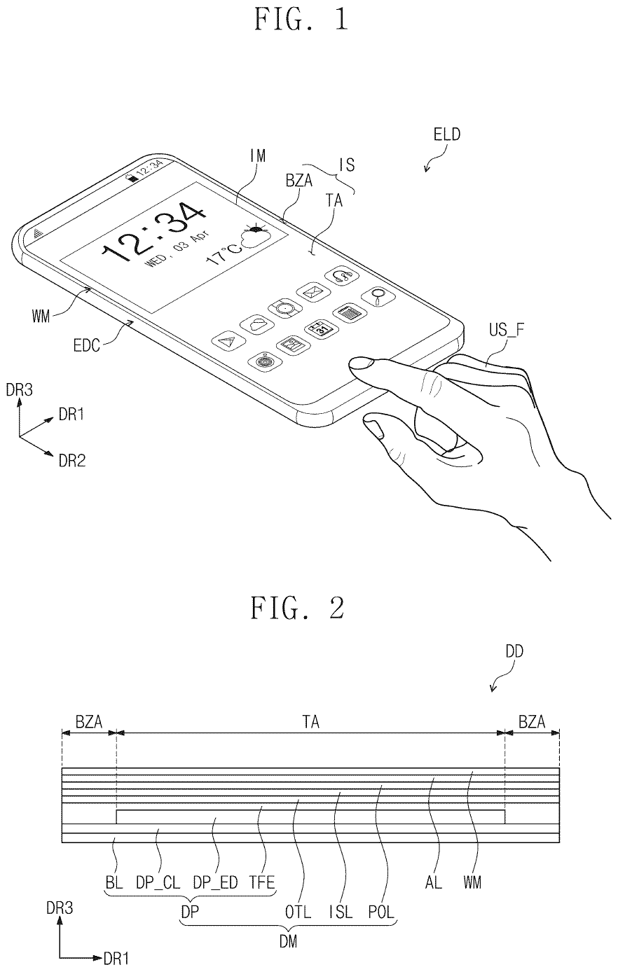

FIG. 1 is a perspective view of an electronic device according to some embodiments of the present disclosure. FIG. 2 is a cross-sectional view of a display device according to some embodiments of the present disclosure.

Referring to FIGS. 1 and 2, the electronic device ELD may have a rectangular shape with short sides parallel to a first direction DR1 and long sides parallel to a second direction DR2 intersecting the first direction DR1. However, the shape of the electronic device ELD should not be limited to the rectangular shape, and the electronic device ELD may have a variety of shapes, such as a circular shape, a polygonal shape, or the like.

The electronic device ELD may be activated in response to electrical signals. The electronic device ELD may be implemented in various embodiments. As an example, the electronic device ELD may be applied to electronic devices, such as a smart watch, a tablet computer, a notebook computer, a computer, or a smart television, etc.

Hereinafter, a normal line direction perpendicular (or substantially perpendicular) to a plane defined by the first direction DR1 and the second direction DR2 is referred to as a third direction DR3. In the following descriptions, the expressions “when viewed in a plane” or “in a plan view” may mean a state of being viewed from the third direction DR3 (e.g., toward a display surface of the electronic device ELD).

An upper surface of the electronic device ELD may be defined as a display surface IS and may be parallel (or substantially parallel) to the plane defined by the first direction DR1 and the second direction DR2. Images IM generated by the electronic device ELD may be provided to a user through the display surface IS.

The display surface IS may be divided into a transmission area TA and a bezel area BZA. The images IM may be displayed through the transmission area TA. The user may view the images IM through the transmission area TA. According to some embodiments, the transmission area TA may have a quadrangular shape with rounded vertices. However, this is merely one example, and the transmission area TA may have a variety of shapes and should not be particularly limited.

The bezel area BZA may be defined adjacent to the transmission area TA. The bezel area BZA may have a selected color. The bezel area BZA may surround the transmission area TA. Accordingly, the shape of the transmission area TA may be defined by the bezel area BZA, however, this is merely one example. According to some embodiments, the bezel area BZA may be located adjacent to only one side of the transmission area TA or may be omitted.

The electronic device ELD may sense an external input applied thereto from the outside. The external input may include a variety of external inputs provided from the outside. For example, the external input may include an external input (e.g., a hovering input) detected when in proximity to or approaching close to the electronic device ELD at a selected distance, as well as a touch input from a part of the user's body, e.g., a finger of the user US_F or from a separate device, e.g., an active pen, a digitizer, or the like. In addition, the external input may take various forms, such as force, pressure, temperature, or light.

The electronic device ELD may sense biometric information of the user, which is applied from the outside. The electronic device ELD may include a biometric information sensing area defined in the display surface IS to sense the biometric information of the user. The biometric information sensing area may be defined across an entire portion of the transmission area TA or within a portion of the transmission area TA. FIG. 1 shows a structure in which the entire portion of the transmission area TA is used as the biometric information sensing area.

The electronic device ELD may include a window WM, a display module DM, and a housing EDC. According to some embodiments, the window WM and the housing EDC may be coupled to each other to form the exterior of the display device DD.

A front surface of the window WM may define the display surface IS of the electronic device ELD. The window WM may include an optically transparent insulating material. For example, the window WM may include a glass or plastic material. The window WM may have a single-layer or multi-layer structure. As an example, the window WM may include a plurality of plastic films coupled to each other by an adhesive or a glass substrate and a plastic film coupled to the glass substrate by an adhesive.

The display module DM may include a display panel DP, an optical layer OTL, an input sensing layer ISL, and a polarizing layer POL. The display panel DP may display images in response to electrical signals, and the input sensing layer ISL may sense external inputs applied from the outside. The external inputs may be provided in various forms.

The display panel DP according to some embodiments of the present disclosure may be a light-emitting type display panel, however, it should not be particularly limited. For instance, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum dot light emitting display panel may include a quantum dot or a quantum rod. Hereinafter, the organic light emitting display panel will be described as a representative example of the display panel DP.

Referring to FIG. 2, the display panel DP may include a base layer BL, a circuit layer DP_CL, an element layer DP_ED, and an encapsulation layer TFE. The display panel DP may be a flexible display panel, however, embodiments according to the present disclosure are not limited thereto or thereby. As an example, the display panel DP may be a foldable display panel folded with respect to a folding axis or a rigid display panel.

The base layer BL may include a synthetic resin layer. The synthetic resin layer may be a polyimide-based resin layer, however, a material for the synthetic resin layer should not be particularly limited. In addition, the base layer BL may include a glass substrate, a metal substrate, or an organic/inorganic composite material substrate.

The circuit layer DP_CL may be located on the base layer BL. The circuit layer DP_CL may be located between the base layer BL and the element layer DP_ED. The circuit layer DP_CL may include at least one insulating layer and a circuit element. Hereinafter, the insulating layer included in the circuit layer DP_CL is referred to as an intermediate insulating layer. The intermediate insulating layer may include at least one intermediate inorganic layer and at least one intermediate organic layer. The circuit element may include a pixel circuit included in each of pixels displaying the images and a sensor circuit included in each of sensors recognizing external information. The external information may be the biometric information. As an example, the sensor may be a fingerprint recognition sensor, a proximity sensor, an iris recognition sensor, a blood pressure measurement sensor, an illumination sensor, or the like. In addition, the sensor may be an optical sensor that recognizes the biometric information in an optical manner. The circuit layer DP_CL may further include signal lines connected to the pixel circuit and/or the sensor circuit.

The element layer DP_ED may include a light emitting element included in each of the pixels and a light receiving element included in each of the sensors. As an example, the light receiving element may be a photodiode. The light receiving element may be a sensor that senses a light reflected by a user's fingerprint or responds to the light.

The encapsulation layer TFE may encapsulate the element layer DP_ED. The encapsulation layer TFE may include at least one organic layer and at least one inorganic layer. The inorganic layer may include an inorganic material and may protect the element layer DP_ED from moisture and oxygen. The inorganic layer may include a silicon nitride layer, a silicon oxynitride layer, a silicon oxide layer, a titanium oxide layer, or an aluminum oxide layer, however, it should not be particularly limited. The organic layer may include an organic material and may protect the element layer DP_ED from a foreign substance such as dust particles.

The optical layer OTL may be located on the display panel DP. The optical layer OTL may form an optical system to transmit light to the light receiving element. According to some embodiments, the optical layer OTL may be formed on the display panel DP through a continuous process. That is, when the optical layer OTL is located directly on the encapsulation layer TFE of the display panel DP, a separate adhesive film may not be located between the optical layer OTL and the encapsulation layer TFE.

The input sensing layer ISL may be located on the optical layer OTL. The input sensing layer ISL may be located directly on the optical layer OTL. The input sensing layer ISL may be formed on the optical layer OTL through a continuous process. That is, when the input sensing layer ISL is located directly on the optical layer OTL, an adhesive member may not be located between the input sensing layer ISL and the optical layer OTL. Alternatively, an adhesive film may be located between the input sensing layer ISL and the optical layer OTL. In this case, the input sensing layer ISL may be fixed onto an upper surface of the display panel DP by the adhesive film after being formed separately from the display panel DP and the optical layer OTL.

The input sensing layer ISL may sense the external input, e.g., a user's touch, may convert the external input to an input signal, and may apply the input signal to the display panel DP. The input sensing layer ISL may include a plurality of sensing electrodes to sense the external input. The sensing electrodes may sense the external input by a capacitance method. The display panel DP may receive an input signal from the input sensing layer ISL and may generate an image corresponding to the input signal.

The position of the optical layer OTL should not be limited to that shown in FIG. 2. As an example, the optical layer OTL may be located on the input sensing layer ISL. In this case, the input sensing layer ISL may be located directly on the encapsulation layer TFE, and the optical layer OTL may be located directly on the input sensing layer ISL.

The display module DM may further include a polarizing layer POL. As an example, the polarizing layer POL may be located on the input sensing layer ISL, however, the present disclosure should not be limited thereto or thereby. When the optical layer OTL is located on the input sensing layer ISL, the polarizing layer POL may be located on the optical layer OTL. The optical layer OTL may include a black matrix through which a transmissive hole is defined.

The polarizing layer POL may include a transmission axis and an absorption axis perpendicular to the transmission axis. Accordingly, the polarizing layer POL may transmit light components that vibrate in a direction parallel to the transmission axis and may absorb light components that vibrate in a direction parallel to the absorption axis. As an example, the transmission axis and the absorption axis of the polarizing layer POL may be inclined with respect to the first and second directions DR1 and DR2. As an example, the transmission axis may be parallel to a diagonal direction inclined at an angle of 45° (or about 45°) with respect to the first direction DR1, and the absorption axis may be parallel to a diagonal direction inclined at an angle of 45° (or about 45°) with respect to the second direction DR2.

The display device DD may further include an adhesive layer AL. The window WM may be attached to the polarizing layer POL by the adhesive layer AL. The adhesive layer AL may include an optically clear adhesive (OCA), an optically clear adhesive resin (OCR), or a pressure sensitive adhesive (PSA).

The housing EDC may be coupled to the window WM. The housing EDC and the window WM coupled to the housing EDC may provide an inner space. The display module DM may be accommodated in the inner space. The housing EDC may include a material with a relatively high rigidity. For example, the housing EDC may include a glass, plastic, or metal material or a plurality of frames and/or plates of combinations thereof. The housing EDC may stably protect the components of the display device DD accommodated in the inner space from external impacts. According to some embodiments, a battery module may be located between the display module DM and the housing EDC to supply a power source required for an overall operation of the display device DD.

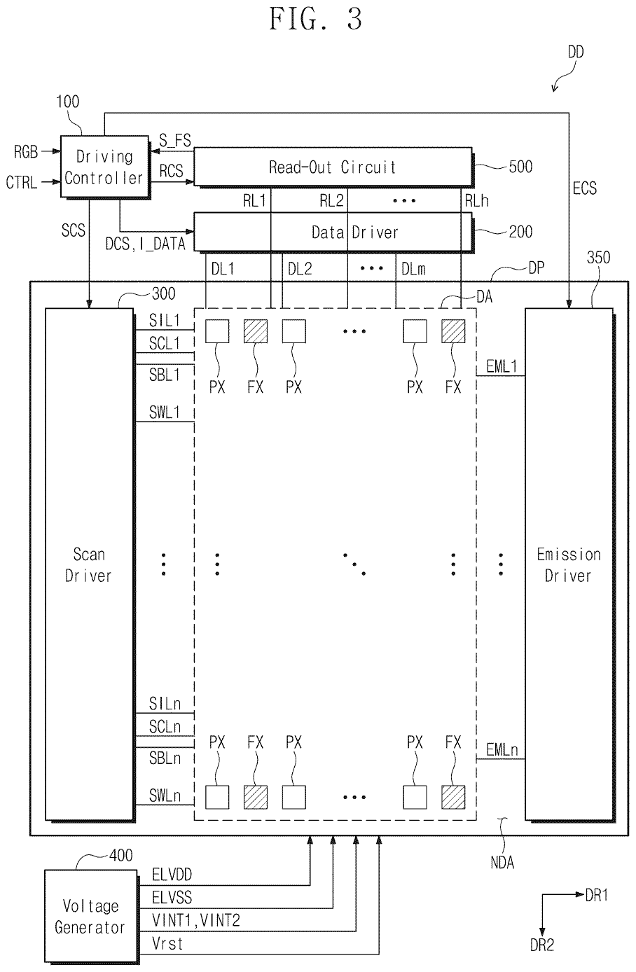

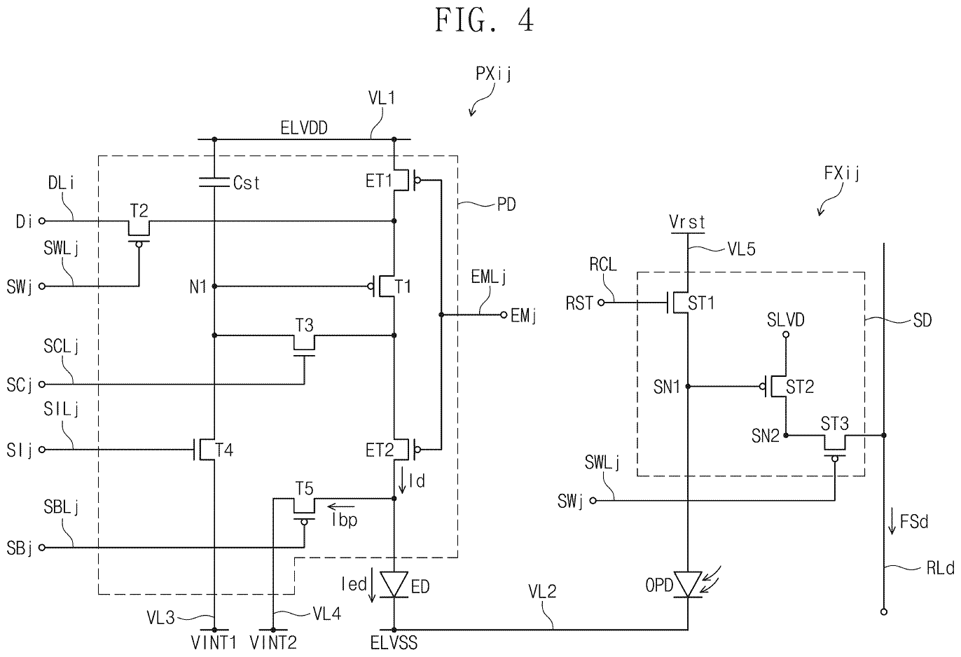

FIG. 3 is a block diagram of the display device according to some embodiments of the present disclosure.

Referring to FIG. 3, the display device DD may include the display panel DP, a panel driver, and a driving controller 100. As an example, the panel driver may include a data driver 200, a scan driver 300, an emission driver 350, a voltage generator 400, and a read-out circuit 500.

The driving controller 100 may receive an image signal RGB and control signals CTRL. The driving controller 100 may convert a data format of the image signal RGB to a data format appropriate to an interface between the data driver 200 and the driving controller 100 to generate image data I_DATA. The driving controller 100 may generate a first control signal SCS, a second control signal ECS, a third control signal DCS, and a fourth control signal RCS.

The data driver 200 may receive the third control signal DCS and the image data I_DATA from the driving controller 100. The data driver 200 may convert the image data I_DATA to data signals and may output the data signals to a plurality of data lines DL1 to DLm described later. The data signals may be analog voltages corresponding to grayscale values of the image data I_DATA.

The scan driver 300 may receive the first control signal SCS from the driving controller 100. The scan driver 300 may output scan signals to scan lines in response to the first control signal SCS.

The voltage generator 400 may generate voltages required to operate the display panel DP. According to some embodiments, the voltage generator 400 may generate a first driving voltage ELVDD, a second driving voltage ELVSS, a first initialization voltage VINT1, a second initialization voltage VINT2, and a reset voltage Vrst.

The display panel DP may include a display area DA corresponding to the transmission area TA (refer to FIG. 1) and a non-display area NDA corresponding to the bezel area BZA (refer to FIG. 1).

The display panel DP may include a plurality of pixels PX located in the display area DA and a plurality of sensors FX located in the display area DA. As an example, each of the sensors FX may be located between two pixels PX adjacent to each other. The pixels PX and the sensors FX may be alternately arranged with each other in the first and second directions DR1 and DR2, however, the present disclosure should not be limited thereto or thereby. That is, two or more pixels PX may be located between two sensors FX adjacent to each other in the first direction DR1 among the sensors FX, or two or more pixels PX may be located between two sensors FX adjacent to each other in the second direction DR2 among the sensors FX.

The display panel DP may further include initialization scan lines SIL1 to SILn, compensation scan lines SCL1 to SCLn, write scan lines SWL1 to SWLn, black scan lines SBL1 to SBLn, emission control lines EML1 to EMLn, the data lines DL1 and DL2 to DLm, and read-out lines RL1 and RL2 to RLh. The initialization scan lines SIL1 to SILn, the compensation scan lines SCL1 to SCLn, the write scan lines SWL1 to SWLn, the black scan lines SBL1 to SBLn, and the emission control lines EML1 to EMLn may extend in the first direction DR1. The initialization scan lines SIL1 to SILn, the compensation scan lines SCL1 to SCLn, the write scan lines SWL1 to SWLn, the black scan lines SBL1 to SBLn, and the emission control lines EML1 to EMLn may be arranged in the second direction DR2 and may be spaced apart from each other. The data lines DL1 to DLm and the read-out lines RL1 to RLh may extend in the second direction DR2 and may be arranged spaced apart from each other in the first direction DR1.

The pixels PX may be electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and the data lines DL1 to DLm. Each of the pixels PX may be electrically connected to four scan lines. However, the number of the scan lines connected to each of the pixels PX should not be limited thereto or thereby.

The sensors FX may be electrically connected to the write scan lines SWL1 to SWLn and the read-out lines RL1 to RLh. Each of the sensors FX may be electrically connected to one scan line, however, the present disclosure should not be limited thereto or thereby. The number of the scan lines connected to each of the sensors FX may vary. As an example, the number of the read-out lines RL1 to RLh may be smaller than or equal to the number of the data lines DL1 to DLm. As an example, the number of the read-out lines RL1 to RLh may correspond to a ½, ¼, or ⅛ of the number of the data lines DL1 to DLm.

The scan driver 300 may be located in the non-display area NDA of the display panel DP. The scan driver 300 may receive the first control signal SCS from the driving controller 100. Responsive to the first control signal SCS, the scan driver 300 may output initialization scan signals to the initialization scan lines SIL1 to SILn and may output compensation scan signals to the compensation scan lines SCL1 to SCLn. In addition, responsive to the first control signal SCS, the scan driver 300 may output write scan signals to the write scan lines SWL1 to SWLn and may output black scan signals to the black scan lines SBL1 to SBLn. Alternatively, the scan driver 300 may include first and second scan drivers. The first scan driver may output the initialization scan signals and the compensation scan signals, and the second scan driver may output the write scan signals and the black scan signals.

The emission driver 350 may be located in the non-display area NDA of the display panel DP. The emission driver 350 may receive the second control signal ECS from the driving controller 100. The emission driver 350 may output light emission control signals to the emission control lines EML1 to EMLn in response to the second control signal ECS. According to some embodiments, alternatively, the scan driver 300 may be connected to the emission control lines EML1 to EMLn. In this case, the emission driver 350 may be omitted, and the scan driver 300 may output the light emission control signals to the emission control lines EML1 to EMLn.

The read-out circuit 500 may receive the fourth control signal RCS from the driving controller 100. The read-out circuit 500 may receive sensing signals from the read-out lines RL1 to RLh in response to the fourth control signal RCS. The read-out circuit 500 may process the sensing signals from the read-out lines RL1 to RLh and may provide the processed sensing signals S_FS to the driving controller 100. The driving controller 100 may recognize the biometric information based on the sensing signals S_FS.

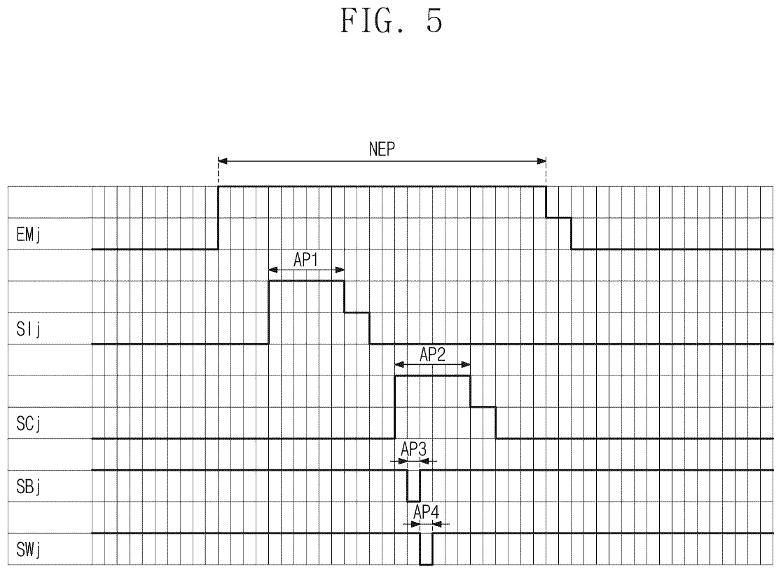

FIG. 4 is a circuit diagram of the pixel and the sensor according to some embodiments of the present disclosure, and FIG. 5 is a waveform diagram of an operation of the pixel and the sensor shown in FIG. 4.

FIG. 4 shows an equivalent circuit diagram of one pixel PXij among the pixels PX shown in FIG. 3. Because the pixels PX have the same (or substantially the same) circuit configuration, the circuit configuration of one pixel PXij will be described in more detail, and some description of the other pixels may be omitted. In addition, FIG. 4 shows an equivalent circuit diagram of one sensor FXij of the sensors FX shown in FIG. 3. Because the sensors FX have the same (or substantially the same) circuit configuration, the circuit configuration of one sensor FXij will be described in more detail, and some description of the other sensors may be omitted.

Although FIG. 4 illustrates various components in a pixel and a sensor according to some embodiments, embodiments according to the present disclosure are not limited thereto, and according to various embodiments, the pixel and/or the sensor may include additional components, or fewer components, unless otherwise stated or implied, without departing from the spirit and scope of embodiments according to the present disclosure.

Referring to FIGS. 3 and 4, the pixel PXij may be connected to an i-th data line DLi among the data lines DL1 to DLm, a j-th initialization scan line SILj among the initialization scan lines SIL1 to SILn, a j-th compensation scan line SCLj among the compensation scan lines SCL1 to SCLn, a j-th write scan line SWLj among the write scan lines SWL1 to SWLn, a j-th black scan line SBLj among the black scan lines SBL1 to SBLn, and a j-th emission control line EMLj among the emission control lines EML1 to EMLn.

The pixel PXij may include a light emitting element ED and a pixel circuit PD. The light emitting element ED may be a light emitting diode. As an example, the light emitting element ED may be an organic light emitting diode including an organic light emitting layer.

The pixel circuit PD may include first, second, third, fourth, and fifth transistors T1, T2, T3, T4, and T5, first and second emission control transistors ET1 and ET2, and one capacitor Cst. At least one of the first to fifth transistors T1 to T5 and the first and second emission control transistors ET1 and ET2 may be a transistor including a low-temperature polycrystalline silicon (LTPS) semiconductor layer. Some transistors of the first to fifth transistors T1 to T5 and the first and second emission control transistors ET1 and ET2 may be a P-type transistor, and the other transistors may be an N-type transistor. As an example, each of the first, second, and fifth transistors T1, T2, and T5 and the first and second emission control transistors ET1 and ET2 may be a PMOS transistor, and each of the third and fourth transistors T3 and T4 may be an NMOS transistor. At least one of the first to fifth transistors T1 to T5 or the first or second emission control transistors ET1 or ET2 may be a transistor including an oxide semiconductor layer. As an example, the third and fourth transistors T3 and T4 may be the oxide semiconductor transistor, and the first, second, and fifth transistors T1, T2, and T5 and the first and second emission control transistors ET1 and ET2 may be an LTPS transistor.

The circuit configuration of the pixel circuit PD according to the present disclosure should not be limited to the embodiments shown in FIG. 4. The pixel circuit PD shown in FIG. 4 is merely an example, and the circuit configuration of the pixel circuit PD may be changed. As an example, all the first to fifth transistors T1 to T5 and the first and second emission control transistors ET1 and ET2 may be the P-type transistor or the N-type transistor.

The j-th initialization scan line SILj, the j-th compensation scan line SCLj, the j-th write scan line SWLj, the j-th black scan line SBLj, and the j-th emission control line EMLj may transmit a j-th initialization scan signal SIj, a j-th compensation scan signal SCj, a j-th write scan signal SWj, a j-th black scan signal SBj, and a j-th emission control signal EMj to the pixel PXij, respectively. The i-th data line DLi may transmit an i-th data signal Di to the pixel PXij. The i-th data signal Di may have a voltage level corresponding to the image signal RGB input to the display device DD.

First and second driving voltage lines VL1 and VL2 may respectively transmit the first driving voltage ELVDD and the second driving voltage ELVSS to the pixel PXij. In addition, first and second initialization voltage lines VL3 and VL4 may respectively transmit the first initialization voltage VINT1 and the second initialization voltage VINT2 to the pixel PXij.

The first transistor T1 may be connected between the first driving voltage line VL1 to which the first driving voltage ELVDD is applied and the light emitting element ED. The first transistor T1 may be referred to as a driving transistor. The first transistor T1 may include a first electrode connected to the first driving voltage line VL1 through the first emission control transistor ET1, a second electrode connected to an anode of the light emitting element ED through the second emission control transistor ET2, and a third electrode, e.g., a gate electrode, connected to one end, e.g., a first node N1, of the capacitor Cst. The first transistor T1 may receive the i-th data signal Di via the i-th data line DLi according to a switching operation of the second transistor T2 and may supply a driving current Id to the light emitting element ED.

The second transistor T2 may be connected between the i-th data line DLi and the first electrode of the first transistor T1. The second transistor T2 may be referred to as a switching transistor. The second transistor T2 may include a first electrode connected to the i-th data line DLi, a second electrode connected to the first electrode of the first transistor T1, and a third electrode, e.g., a gate electrode, connected to the j-th write scan line SWLj. The second transistor T2 may be turned on in response to the j-th write scan signal SWj applied through the j-th write scan line SWLj and may transmit the i-th data signal Di provided from the i-th data line DLi to the first electrode of the first transistor T1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode, e.g., a gate electrode, connected to the j-th compensation scan line SCLj. The third transistor T3 may be turned on in response to the j-th compensation scan signal SCj applied through the j-th compensation scan line SCLj and may connect the second electrode and the third electrode of the first transistor T1, and thus, the first transistor T1 may be connected in a diode configuration.

The fourth transistor T4 may be connected between the first initialization voltage line VL3 to which the first initialization voltage VINT1 is applied and the first node N1. The fourth transistor T4 may include a first electrode connected to the first initialization voltage line VL3 to which the first initialization voltage VINT1 is applied, a second electrode connected to the first node N1, and a third electrode, e.g., a gate electrode, connected to the j-th initialization scan line SILj. The fourth transistor T4 may be turned on in response to the j-th initialization scan signal SIj applied the through the j-th initialization scan line SILj. The turned-on fourth transistor T4 may supply the first initialization voltage VINT1 to the first node N1 to initialize an electric potential of the third electrode of the first transistor T1, i.e., an electric potential of the first node N1.

The first emission control transistor ET1 may include a first electrode connected to the first driving voltage line VL1, a second electrode connected to the first electrode of the first transistor T1, and a third electrode, e.g., a gate electrode, connected to the j-th emission control line EMLj.

The second emission control transistor ET2 may include a first electrode connected to the second electrode of the first transistor T1, a second electrode connected to the anode electrode of the light emitting element ED, and a third electrode, e.g., a gate electrode, connected to the j-th emission control line EMLj.

The first and the second emission control transistors ET1 and ET2 may be simultaneously or concurrently (or substantially simultaneously) turned on in response to the j-th emission control signal EMj applied through the j-th emission control line EMLj. The first driving voltage ELVDD provided through the turned-on first emission control transistor ET1 may be compensated for through the diode-connected first transistor T1 and then may be supplied to the light emitting element ED.

The fifth transistor T5 may include a first electrode connected to the second initialization voltage line VL4 to which the second initialization voltage VINT2 is applied, a second electrode connected to the second electrode of the second emission control transistor ET2, and a third electrode, e.g., a gate electrode, connected to the j-th black scan line SBLj. The second initialization voltage VINT2 may have a voltage level lower than or equal to that of the first initialization voltage VINT1.

As described above, the one end of the capacitor Cst may be connected to the third electrode of the first transistor T1, and the other end of the capacitor Cst may be connected to the first driving voltage line VL1. A cathode of the light emitting element ED may be connected to the second driving voltage line VL2 transmitting the second driving voltage ELVSS. The second driving voltage ELVSS may have a voltage level lower than that of the first driving voltage ELVDD. As an example, the second driving voltage ELVSS may have a voltage level lower than that of the first and second initialization voltages VINT1 and VINT2.

Referring to FIGS. 4 and 5, the j-th emission control signal EMj may have a high level during a non-emission period NEP. The j-th initialization scan signal SIj may be activated within the non-emission period NEP. When the j-th initialization scan signal SIj having the high level is provided through the j-th initialization scan line SILj during an activation period AP1 (hereinafter, referred to as a first activation period) of the j-th initialization scan signal SIj, the fourth transistor T4 may be turned on in response to the j-th initialization scan signal SIj having the high level. The first initialization voltage VINT1 may be applied to the third electrode of the first transistor T1 through the turned-on fourth transistor T4, and the first node N1 may be initialized to the first initialization voltage VINT1. Accordingly, the first activation period AP1 may be defined as an initialization period of the pixel PXij.

Then, when the j-th compensation scan signal SCj is activated and the j-th compensation scan signal SCj having the high level is provided through the j-th compensation scan line SCLj during an activation period AP2 (hereinafter, referred to as a second activation period) of the j-th compensation scan signal SCj, the third transistor T3 may be turned on. The first transistor T1 may be connected in a diode configuration by the turned-on third transistor T3 and may be forward biased. The first activation period AP1 may not overlap the second activation period AP2.

The j-th write scan signal SWj may be activated within the second activation period AP2. The j-th write scan signal SWj may have a low level during an activation period AP4 (hereinafter, referred to as a fourth activation period). The second transistor T2 may be turned on in response to the j-th write scan signal SWj having the low level during the fourth activation period AP4. Then, a compensation voltage “Di-Vth”, which is reduced by a threshold voltage Vth of the first transistor T1 from the i-th data signal Di provided through the i-th data line DLi, may be applied to the third electrode of the first transistor T1. That is, an electric potential of the third electrode of the first transistor T1 may be the compensation voltage “Di-Vth”. The fourth activation period AP4 may overlap the second activation period AP2. A duration of the second activation period AP2 may be longer than a duration of the fourth activation period AP4.

The first driving voltage ELVDD and the compensation voltage “Di-Vth” may be respectively applied to opposite ends of the capacitor Cst, and the capacitor Cst may be charged with electric charges corresponding to a difference in voltage between the opposite ends of the capacitor Cst. A high level period of the j-th compensation scan signal SCj may be referred to as a compensation period of the pixel PXij.

The j-th black scan signal SBj may be activated within the second activation period AP2 of the j-th compensation scan signal SCj. The j-th black scan signal SBj may have the low level during an activation period AP3 (hereinafter, referred to as a third activation period). During the third activation period AP3, the fifth transistor T5 may be turned on in response to the j-th black scan signal SBj having the low level applied through the j-th black scan line SBLj. A portion of the driving current Id may be bypassed as a bypass current Ibp via the fifth transistor T5. The third activation period AP3 may overlap the second activation period AP2. The duration of the second activation period AP2 may be longer than a duration of the third activation period AP3. The third activation period AP3 may precede the fourth activation period AP4 and may not overlap the fourth activation period AP4.

In a case where the pixel PXij displays a black image, if the light emitting element ED emits light even when a minimum driving current of the first transistor T1 flows as the driving current Id, the pixel PXij may not properly display the black image. Therefore, in the pixel PXij according to some embodiments of the present disclosure, the fifth transistor T5 may divert part of the minimum driving current of the first transistor T1 as the bypass current Ibp along a path different from the current path to the light emitting element ED. In this case, the minimum driving current of the first transistor T1 may refer to a current flowing through the first transistor T1 under a condition that a gate-source voltage Vgs of the first transistor T1 is lower than the threshold voltage Vth and the first transistor T1 is turned off. The minimum driving current flowing through the first transistor T1 under the condition that the first transistor T1 is turned off, for example, a current of less than 10 pA (or about 10 pA), is transmitted to the light emitting element ED, and an image with a black grayscale may be displayed. In the case where the pixel PXij displays the black image, an influence of the bypass current Ibp on the minimum driving current is relatively large, however, in the case where images, such as a normal image or a white image, are displayed, the influence of the bypass current Ibp on the driving current Id may be considered negligible. Accordingly, when the black image is displayed, a current, i.e., a light emitting current Ied, which is reduced by an amount of the bypass current Ibp flowing out from the driving current Id through the fifth transistor T5, may be provided to the light emitting element ED, enabling a more accurate representation of the black image. Thus, the pixel PXij may display an accurate black grayscale image utilizing the fifth transistor T5, and as a result, a contrast ratio may be improved.

Then, a level of the j-th emission control signal EMj provided from the j-th emission control line EMLj may be changed to the low level from the high level. The first and second emission control transistors ET1 and ET2 may be turned on in response to the j-th emission control signal EMj having the low level. As a result, the driving current Id may be generated due to a difference in voltage between the voltage of the gate of the first transistor T1 and the first driving voltage ELVDD, the driving current Id may be supplied to the light emitting element ED via the second emission control transistor ET2, and thus, the light emitting current Ied may flow through the light emitting element ED.

Referring to FIG. 4 again, the sensor FXij may be connected to a d-th read-out line RLd among the read-out lines RL1 to RLh, the j-th write scan line SWLj, and a reset control line RCL.

The sensor FXij may include a light receiving element OPD and a sensor circuit SD. FIG. 4 shows a structure in which the sensor FXij includes one light sensing element as a representative example, however, the present disclosure should not be limited thereto or thereby. As an example, the sensor FXij may include two or more light sensing elements OPD connected to each other in parallel. The light receiving element OPD may be a photodiode As an example, the light receiving element OPD may be an organic photodiode including an organic material as a photoelectric conversion layer.

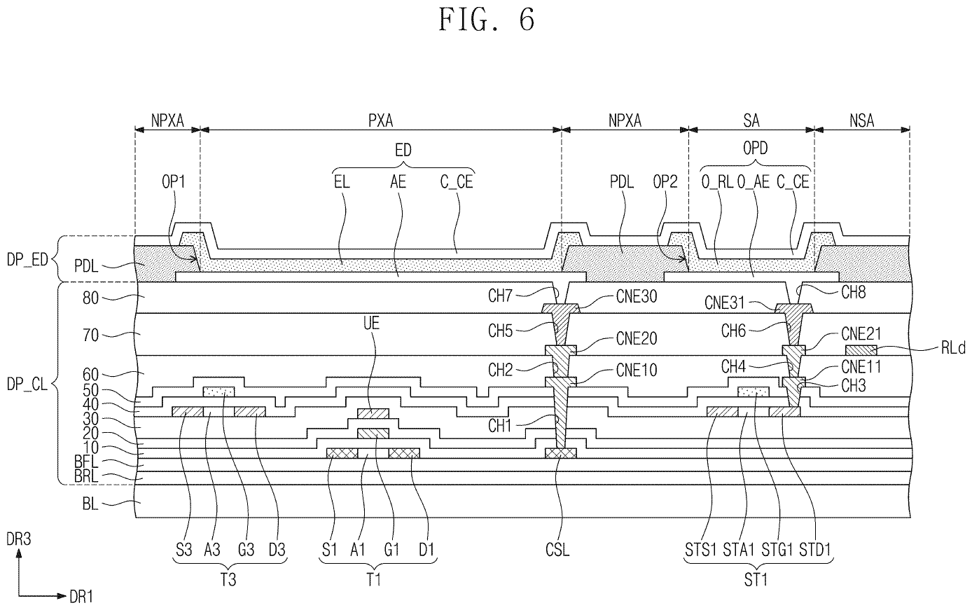

An anode electrode of the light receiving element OPD may be connected to a first sensing node SN1, and a cathode electrode of the light receiving element OPD may be connected to the second driving voltage line VL2 transmitting the second driving voltage ELVSS. The cathode electrode of the light receiving element OPD may be electrically connected to the cathode electrode of the light emitting element ED. As an example, the cathode electrode of the light receiving element OPD may be formed integrally with the cathode electrode of the light emitting element ED to form a common cathode electrode C-CE (refer to FIG. 6).

The sensor circuit SD may include three transistors ST1, ST2, and ST3. The three transistors ST1, ST2, and ST3 may be a reset transistor ST1, an amplification transistor ST2, and an output transistor ST3, respectively. At least one of the reset transistor ST1, the amplification transistor ST2, or the output transistor ST3 may be an oxide semiconductor transistor. As an example, the reset transistor ST1 may be the oxide semiconductor transistor, and the amplification transistor ST2 and the output transistor ST3 may be the LTPS transistor, however, the present disclosure should not be limited thereto or thereby. According to some embodiments, at least the reset transistor ST1 and the output transistor ST3 may be the oxide semiconductor transistor, and the amplification transistor ST2 may be the LTPS transistor.

In addition, some of the reset transistor ST1, the amplification transistor ST2, and the output transistor ST3 may be the P-type transistor, and the other transistors may be the N-type transistor. As an example, the amplification transistor ST2 and the output transistor ST3 may be the PMOS transistor, and the reset transistor ST1 may be the NMOS transistor, however, embodiments according to the present disclosure are not limited thereto or thereby. According to some embodiments, the reset transistor ST1, the amplification transistor ST2, and the output transistor ST3 may all be the N-type transistor or may all be the P-type transistor.

One or more transistors, for example, the reset transistor ST1, among the reset transistor ST1, the amplification transistor ST2, and the output transistor ST3 may be the same type of transistor as the third and fourth transistors T3 and T4 of the pixel PXij. The amplification transistor ST2 and the output transistor ST3 may be the same type of transistor as the first, second, and fifth transistors T1, T2, and T5 and the first and second emission control transistors ET1 and ET2 of the pixel PXij.

The circuit configuration of the sensor circuit SD should not be limited to that shown in FIG. 4. The sensor circuit SD shown in FIG. 4 is merely an example, and the circuit configuration of the sensor circuit SD may be modified in various ways.

The reset transistor ST1 may include a first electrode receiving the reset voltage Vrst, a second electrode connected to the first sensing node SN1, and a third electrode receiving a reset control signal RST. The reset transistor ST1 may reset an electric potential of the first sensing node SN1 to the reset voltage Vrst in response to the reset control signal RST. The reset control signal RST may be a signal provided through the reset control line RCL, however, the present disclosure should not be limited thereto or thereby. Alternatively, the reset control signal RST may be the j-th compensation scan signal SCj provided through the j-th compensation scan line SCLj. That is, the reset transistor ST1 may receive the j-th compensation scan signal SCj provided through the j-th compensation scan line SCLj as the reset control signal RST. As an example, the reset voltage Vrst may have a voltage level lower than that of the second driving voltage ELVSS at least during an activation period of the reset control signal RST. The reset voltage Vrst may be a DC voltage maintained at a voltage level lower than that of the second driving voltage ELVSS.

The reset transistor ST1 may include a plurality of sub-reset transistors connected to each other in series. As an example, the reset transistor ST1 may include two sub-reset transistors (hereinafter, first and second sub-reset transistors). In this case, a third electrode of the first sub-reset transistor and a third electrode of the second sub-reset transistor may be connected to the reset control line RCL. In addition, a second electrode of the first sub-reset transistor and a first electrode of the second sub-reset transistor may be electrically connected to each other. In addition, the reset voltage Vrst may be applied to a first electrode of the first sub-reset transistor, and a second electrode of the second sub-reset transistor may be electrically connected to the first sensing node SN1. However, the number of sub-reset transistors should not be limited thereto or thereby.

The amplification transistor ST2 may include a first electrode receiving a sensing driving voltage SLVD, a second electrode connected to a second sensing node SN2, and a third electrode connected to the first sensing node SN1. The amplification transistor ST2 may be turned on depending on the electric potential of the first sensing node SN1 and may apply the sensing driving voltage SLVD to the second sensing node SN2. As an example, the sensing driving voltage SLVD may be one of the first driving voltage ELVDD and the first and second initialization voltages VINT1 and VINT2. When the sensing driving voltage SLVD is the first driving voltage ELVDD, the first electrode of the amplification transistor ST2 may be electrically connected to the first driving voltage line VL1. When the sensing driving voltage SLVD is the first initialization voltage VINT1, the first electrode of the amplification transistor ST2 may be electrically connected to the first initialization voltage line VL3, and when the sensing driving voltage SLVD is the second initialization voltage VINT2, the first electrode of the amplification transistor ST2 may be electrically connected to the second initialization voltage line VL4.

The output transistor ST3 may include a first electrode connected to the second sensing node SN2, a second electrode connected to the d-th read-out line RLd, and a third electrode receiving an output control signal. The output transistor ST3 may apply a sensing signal FSd to the d-th read-out line RLd in response to the output control signal. The output control signal may be the j-th write scan signal SWj provided through the j-th write scan line SWLj. That is, the output transistor ST3 may receive the j-th write scan signal SWj provided through the j-th write scan line SWLj as the output control signal. However, embodiments according to the present disclosure are not limited thereto or thereby, and as an example, the output transistor ST3 may receive the j-th compensation scan signal SCj, the j-th initialization scan signal SIj, or the j-th black scan signal SBj as the output control signal.

The light receiving element OPD of the sensor FXij may be exposed to the light during the light emission period of the light emitting element ED. The light may be the light emitted from the light emitting element ED. The light receiving element OPD may generate photo-charges corresponding to the received light, and the generated photo-charges may be accumulated in the first sensing node SN1.

When the user's finger US_F (refer to FIG. 1) touches the display surface in a mode to sense user's information, e.g., a user's fingerprint, the light receiving element OPD may generate photo-charges corresponding to the light reflected by ridges of the user's fingerprint or valleys between the ridges of the user's fingerprint. The amount of current flowing through light receiving element OPD may vary depending on the generated photo-charges. When the light receiving element OPD receives the light reflected by the ridges of the user's fingerprint, the current flowing through the light receiving element OPD may be referred to as a first current, and when the light receiving element OPD receives the light reflected by the valleys of the user's fingerprint, the current flowing through the light receiving element OPD may be referred to as a second current. The amount of the light reflected by the ridges of the user's fingerprint and the amount of the light reflected by the valleys of the user's fingerprint are different from each other, and this difference in light amount is represented as the difference between the first and second currents. When the first current flows through the light receiving element OPD, an electric potential of the first sensing node SN1 may be referred to as a first electric potential, and when the second current flows through the light receiving element OPD, the electric potential of the first sensing node SN1 may be referred to as a second electric potential. As an example, the first current may be greater than the second current, and in this case, the first electric potential may be lower than the second electric potential.

The amplification transistor ST2 may be a source follower amplifier that generates a source-drain current in proportion to the electric potential of the first sensing node SN1 input to the third electrode.

During the fourth activation period AP4, the j-th write scan signal SWj having the low level may be applied to the output transistor ST3 via the j-th write scan line SWLj. When the output transistor ST3 is turned on in response to the j-th write scan signal SWj having the low level, the sensing signal FSd corresponding to a current flowing through the amplification transistor ST2 may be output to the d-th read-out line RLd.

FIG. 6 is a cross-sectional view of the pixel and the sensor of the display panel according to some embodiments of the present disclosure.

Referring to FIG. 6, the display panel DP may include the base layer BL, the circuit layer DP_CL, and the element layer DP_ED.

The base layer BL may include a synthetic resin layer. The synthetic resin layer may include a heat-curable resin. The synthetic resin layer may include a polyimide-based resin, however, a material for the synthetic resin layer should not be particularly limited. The synthetic resin layer may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin. According to some embodiments, the base layer BL may include a glass substrate, a metal substrate, or an organic/inorganic composite material substrate.

At least one inorganic layer may be located on an upper surface of the base layer BL. The inorganic layer may include at least one of aluminum oxide, titanium oxide, silicon oxide, silicon oxynitride, zirconium oxide, or hafnium oxide. The inorganic layer may be formed in multiple layers. The inorganic layers may form a barrier layer BRL and/or a buffer layer BFL. According to some embodiments, the buffer layer BFL and the barrier layer BRL may be selectively located on the base layer BL.

The circuit layer DP_CL may include the barrier layer BRL and/or the buffer layer BFL. The barrier layer BRL may prevent or reduce instances of contaminants or foreign substances entering from the outside. The barrier layer BRL may include a silicon oxide layer and a silicon nitride layer. Each of the silicon oxide layer and the silicon nitride layer may be provided in plural, and the silicon oxide layers may be alternately stacked with the silicon nitride layers.

The buffer layer BFL may be located on the barrier layer BRL. The buffer layer BFL may increase an adhesion between the base layer BL and a semiconductor pattern or between the base layer BL and a conductive pattern. According to some embodiments, the buffer layer BFL may include a silicon oxide layer and a silicon nitride layer. The silicon oxide layer and the silicon nitride layer may be alternately stacked one on another.

The semiconductor pattern may be located on the buffer layer BFL. Hereinafter, the semiconductor pattern located directly on the buffer layer BFL is referred to as a first semiconductor pattern. The first semiconductor pattern may include a silicon semiconductor. The first semiconductor pattern may include polysilicon, however, it should not be limited thereto or thereby. According to some embodiments, the first semiconductor pattern may include amorphous silicon.

FIG. 6 shows only a portion of the first semiconductor pattern, and the first semiconductor pattern may further be located in other areas of the pixel PXij (refer to FIG. 4). The first semiconductor pattern may have different electrical properties depending on whether it is doped or not. The first semiconductor pattern may include a doped region and a non-doped region. The doped region may be doped with the N-type dopant or the P-type dopant. A P-type transistor may include a doped region doped with the P-type dopant, and an N-type transistor may include a doped region doped with the N-type dopant.

The doped region may have a conductivity greater than that of the non-doped region and may serve as an electrode or signal line. The non-doped region may correspond to an active (or a channel) of the transistor. In other words, a portion of the first semiconductor pattern may be the active of the transistor, another portion of the first semiconductor pattern may be a source or a drain of the transistor, and the other portion of the first semiconductor pattern may be a connection signal line (or a connection electrode).

As shown in FIG. 6, a first electrode S1, a channel portion A1, and a second electrode D1 of the first transistor T1 may be formed from the first semiconductor pattern. The first electrode S1 and the second electrode D1 may extend in opposite directions to each other from the channel portion A1.

FIG. 6 shows a portion of a connection signal line CSL formed from the semiconductor pattern. According to some embodiments, the connection signal line CSL may be connected to the second electrode of the second emission control transistor ET2 (refer to FIG. 4) when viewed in a plane (e.g., in a plan view).

A first insulating layer 10 may be located on the buffer layer BFL. The first insulating layer 10 may commonly overlap the pixels PX (refer to FIG. 3) and may cover the first semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon oxynitride, zirconium oxide, or hafnium oxide. According to some embodiments, the first insulating layer 10 may have a single-layer structure of a silicon oxide layer. Not only the first insulating layer 10, but also an insulating layer of the circuit layer DP_CL described in more detail later may be an inorganic layer and/or an organic layer and may have a single-layer or multi-layer structure. The inorganic layer may include at least one of the above-mentioned materials.

A third electrode G1 of the first transistor T1 may be located on the first insulating layer 10. The third electrode G1 may be a portion of a metal pattern. The third electrode G1 of the first transistor T1 may overlap the channel portion A1 of the first transistor T1. The third electrode G1 of the first transistor T1 may be used as a mask in a process of doping the first semiconductor pattern.

A second insulating layer 20 may be located on the first insulating layer 10 and may cover the third electrode G1. The second insulating layer 20 may commonly overlap the pixels PX. The second insulating layer 20 may be an inorganic layer and/or an organic layer and may have a single-layer or multi-layer structure. According to some embodiments, the second insulating layer 20 may have a single-layer structure of a silicon oxide layer.

An upper electrode UE may be located on the second insulating layer 20. The upper electrode UE may overlap the third electrode G1. The upper electrode UE may be a portion of a metal pattern or a portion of the doped semiconductor pattern. A portion of the third electrode G1 and the upper electrode UE overlapping the portion of the third electrode G1 may define the capacitor Cst (refer to FIG. 4). According to some embodiments, the upper electrode UE may be omitted.

According to some embodiments, the second insulating layer 20 may be replaced with an insulating pattern. The upper electrode UE may be located on the insulating pattern. The upper electrode UE may serve as a mask in the process of forming the insulating pattern from the second insulating layer 20.

A third insulating layer 30 may be located on the second insulating layer 20 to cover the upper electrode UE. According to some embodiments, the third insulating layer 30 may have a single-layer structure of a silicon oxide layer. The semiconductor pattern may be located on the third insulating layer 30. Hereinafter, the semiconductor pattern located directly on the third insulating layer 30 is referred to as a second semiconductor pattern. The second semiconductor pattern may include metal oxide. The oxide semiconductor may include a crystalline or amorphous oxide semiconductor. As an example, the oxide semiconductor may include the metal oxide of metals, such as zinc (Zn), indium (In), gallium (Ga), tin (Sn), titanium (Ti), etc., or a mixture of the metal, such as zinc (Zn), indium (In), gallium (Ga), tin (Sn), titanium (Ti), etc., and oxides thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like.

FIG. 6 shows only a portion of the second semiconductor pattern, and the second semiconductor pattern may further be located in other areas of the pixel PXij. The second semiconductor pattern may include a plurality of areas distinguished from each other depending on whether the metal oxide is reduced or not. An area (hereinafter, referred to as a reduced area) where the metal oxide is reduced may have a conductivity higher than that of an area (hereinafter, referred to as a non-reduced area) where the metal oxide is not reduced. The reduced area may act as the electrode or the signal line. The non-reduced area may correspond to the channel portion of the transistor. In other words, a portion of the second semiconductor pattern may be the channel portion of the transistor, and the other portion of the second semiconductor pattern may be the first electrode or the second electrode of the transistor.

The circuit layer DP_CL may further include a portion of the semiconductor pattern of the sensor circuit SD (refer to FIG. 4). For the convenience of explanation, the reset transistor ST1 in the semiconductor pattern of the sensor circuit SD is shown. A first electrode STS1, a channel portion STA1, and a second electrode STD1 of the reset transistor ST1 may be formed from the second semiconductor pattern. As an example, the second semiconductor pattern may include a metal oxide. The first electrode STS1 and the second electrode STD1 may include a metal reduced from the metal oxide semiconductor. The first electrode STS1 and the second electrode STD1 may include a metal layer having a thickness from an upper surface of the second semiconductor pattern and including the reduced metal.

A fourth insulating layer 40 may be arranged to cover the first electrode STS1, the channel portion STA1, and the second electrode STD1 of the reset transistor ST1. A third electrode STG1 of the reset transistor ST1 may be located on the fourth insulating layer 40. According to some embodiments, the third electrode STG1 may be a portion of a metal pattern. The third electrode STG1 of the reset transistor ST1 may overlap the channel portion STA1 of the reset transistor ST1. According to some embodiments, for the convenience of explanation, one third electrode STG1 is shown, however, the reset transistor ST1 may include two third electrodes.

A fifth insulating layer 50 may be located on the fourth insulating layer 40 to cover the third electrode G3. According to some embodiments, the fifth insulating layer 50 may include a silicon oxide layer and a silicon nitride layer. The fifth insulating layer 50 may include silicon oxide layers and silicon nitride layers alternately stacked with the silicon oxide layers.

At least one insulating layer may further be located on the fifth insulating layer 50. A sixth insulating layer 60 and a seventh insulating layer 70 may be located on the fifth insulating layer 50. Each of the sixth insulating layer 60 and the seventh insulating layer 70 may be an organic layer and may have a single-layer or multi-layer structure. Each of the sixth insulating layer 60 and the seventh insulating layer 70 may have a single-layer structure of a polyimide-based resin layer, however, they should not be limited thereto or thereby. According to some embodiments, each of the sixth insulating layer 60 and the seventh insulating layer 70 may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin.

A first connection electrode CNE10 may be located on the fifth insulating layer 50. The first connection electrode CNE10 may be connected to the connection signal line CSL through a first contact hole CH1 defined through the first to fifth insulating layers 10 to 50, and a second connection electrode CNE20 may be connected to the first connection electrode CNE10 through a second contact hole CH2 defined through the sixth insulating layer 60. According to some embodiments of the present disclosure, at least one of the fifth, sixth, or seventh insulating layers 50, 60, and 70 may be omitted, and at least one of the first or second connection electrodes CNE10 or CNE20 may be omitted.

A third connection electrode CNE11 may further be located on the fifth insulating layer 50. The third connection electrode CNE11 may be connected to the second electrode STD1 of the reset transistor ST1 via a third contact hole CH3 defined through the fourth and fifth insulating layers 40 and 50, and a fourth connection electrode CNE21 may be connected to the third connection electrode CNE11 via a fourth contact hole CH4 defined through the sixth insulating layer 60.

The i-th data line DLi (refer to FIG. 4) and the read-out line RLd may be located at the same layer, i.e., the sixth insulating layer 60, as the second and fourth connection electrodes CNE20 and CNE21, however, the present disclosure should not be limited thereto or thereby. Alternatively, the i-th data line DLi (refer to FIG. 4) and the read-out line RLd may be located at the same layer, i.e., the fifth insulating layer 50, as the first and third connection electrodes CNE10 and CNE11. The second and fourth connection electrodes CNE20 and CNE21, the i-th data line DLi, and the read-out line RLd may be covered by the seventh insulating layer 70.

A first dummy connection electrode CNE30 and a second dummy connection electrode CNE31 may further be located on the seventh insulating layer 70. The first dummy connection electrode CNE30 may be connected to the second connection electrode CNE20 via a fifth contact hole CH5 defined through the seventh insulating layer 70. The second dummy connection electrode CNE31 may be connected to the fourth connection electrode CNE21 via a sixth contact hole CH6 defined through the seventh insulating layer 70.

The element layer DP_ED may be located on the circuit layer DP_CL. The element layer DP_ED may include an anode electrode AE of the light emitting element ED and a sensing anode electrode O_AE of the light receiving element OPD. As shown in FIG. 6, the anode electrode AE of the light emitting element ED may be connected to the first dummy connection electrode CNE30 via a seventh contact hole CH7 defined through the eighth insulating layer 80. The sensing anode electrode O_AE of the light receiving element OPD may be connected to the second dummy connection electrode CNE31 via an eighth contact hole CH8 defined through the eighth insulating layer 80.

FIG. 6 shows a structure in which the circuit layer DP_CL include the first dummy connection electrode CNE30 and the second dummy connection electrode CNE31, however, the present disclosure should not be limited thereto or thereby. Alternatively, the first dummy connection electrode CNE30 and the second dummy connection electrode CNE31 may be omitted from the circuit layer. In this case, the anode electrode AE of the light emitting element ED may be directly connected to the second connection electrode CNE20, and the sensing anode electrode O_AE of the light receiving element OPD may be directly connected to the fourth connection electrode CNE21.

The element layer DP_ED may further include a pixel definition layer PDL located on the circuit layer DP_CL. The pixel definition layer PDL may be provided with a light emitting opening OP1 defined to correspond to the light emitting element ED and a light receiving opening OP2 defined to correspond to the light receiving element OPD. The light emitting opening OP1 may expose at least a portion of the anode electrode AE of the light emitting element ED. The light emitting opening OP1 of the pixel definition layer PDL may define a light emitting area PXA. For instance, the pixels PX (refer to FIG. 3) may be arranged in a certain rule on the plane of the display panel DP (refer to FIG. 3). The area where the pixels PX are arranged may be defined as a pixel area, and one pixel area may include the light emitting area PXA and a non-light-emitting area NPXA adjacent to the light emitting area PXA. The non-light-emitting area NPXA may surround the light emitting area PXA.

The sensing anode electrode O_AE of the light receiving element OPD may be exposed through the light receiving opening OP2. The light receiving opening OP2 of the pixel definition layer PDL may define a light receiving area SA. For instance, the sensors FX (refer to FIG. 3) may be arranged in a certain rule on the plane of the display panel DP. The area where the sensors FX (refer to FIG. 3) are arranged may be defined as a sensing area, and one sensing area may include the light receiving area SA and a non-light-receiving area NSA adjacent to the light receiving area SA. The non-light-receiving area NSA may surround the light receiving area SA.

A light emitting layer EL may be arranged to correspond to the light emitting opening OP1 defined through the pixel definition layer PDL, and a photoelectric conversion layer O_RL may be arranged to correspond to the light receiving opening OP2 defined through the pixel definition layer PDL. According to some embodiments, the patterned light emitting layer EL is shown as a representative example, however, the present disclosure should not be limited thereto or thereby. A common light emitting layer C_CE may be commonly arranged in the pixels PX. In this case, the common light emitting layer C_CE may generate a white light or a blue light. The common cathode electrode C_CE may be commonly connected to the light emitting element ED and the light receiving element OPD. The common cathode electrode C_CE may face the sensing anode electrode O_AE of the light receiving element OPD and the anode electrode E_AE of the light emitting element ED. The common cathode electrode C_CE may be located on the light emitting layer EL and the photoelectric conversion layer O_RL. The common cathode electrode C_CE may be commonly arranged over the pixels PX and the sensors FX.

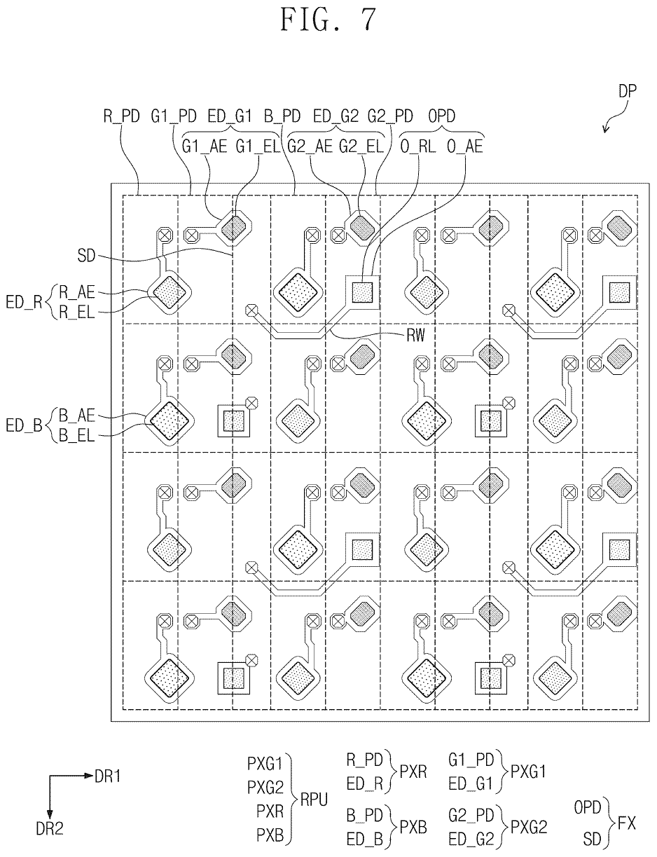

FIG. 7 is an enlarged plan view of a portion of a display panel according to some embodiments of the present disclosure.

Referring to FIG. 7, the display panel DP may include a plurality of pixels PXR, PXG1, PXG2, and PXB and a plurality of sensors FX.

The pixels PXR, PXG1, PXG2, and PXB may be grouped in a plurality of reference pixel units RPU. As an example, each of the reference pixel units RPU may include four pixels, i.e., two first pixels PXG1 and PXG2 (hereinafter, referred to as first and second green pixels), a second pixel PXR (hereinafter, referred to as a red pixel), and a third pixel PXB (hereinafter, referred to as a blue pixel). However, the number of pixels included in each of the reference pixel units RPU should not be limited thereto or thereby. Alternatively, each of the reference pixel units RPU may include three pixels, i.e., the first green pixel PXG1 or the second green pixel PXG2, the red pixel PXR, and the blue pixel PXB.

The first and second green pixels PXG1 and PXG2 may respectively include first and second light emitting elements ED_G1 and ED_G2 (hereinafter, referred to as first and second green light emitting elements), the red pixel PXR may include a third light emitting element ED_R (hereinafter, referred to as a red light emitting element), and the blue pixel PXB may include a fourth light emitting element ED_B (hereinafter, referred to as a blue light emitting element). As an example, each of the first and second green light emitting elements ED_G1 and ED_G2 may emit a first color light, e.g., a green light, the red light emitting element ED_R may emit a second color light, e.g., a red light, different from the first color light, and the blue light emitting element ED_B may emit a third color light, e.g., a blue light, different from the first and second color lights. The green light emitted from the first green light emitting element ED_G1 may have the same wavelength band as that of the green light emitted from the second green light emitting element ED_G2.

In the first and second directions DR1 and DR2, the red light emitting elements ED_R may be alternately and repeatedly arranged with the blue light emitting elements ED_B. The first and second green light emitting elements ED_G1 and ED_G2 may be alternately arranged with each other in the first direction DR1 and may be alternately arranged with each other in the second direction DR2. The first and second green light emitting elements ED_G1 and ED_G2 may be arranged in different rows and columns from rows and columns where the red light emitting elements ED_R and the blue light emitting elements ED_B are arranged in the first and second directions DR1 and DR2.

As an example, the red light emitting element ED_R may have a size greater than that of the first and second green light emitting elements ED_G1 and ED_G2. In addition, the blue light emitting element ED_B may have a size greater than or equal to that of the red light emitting element ED_R. The size of each of the light emitting elements ED_R, ED_G1, ED_G2, and ED_B should not be limited thereto or thereby and may be changed in various ways. For instance, according to some embodiments, the light emitting elements ED_R, ED_G1, ED_G2, and ED_B may have the same size as each other.

The first green light emitting element ED_G1 may be electrically connected to a first green pixel circuit G1_PD. For example, the first green light emitting element ED_G1 may include a first green anode electrode G1_AE and a first green light emitting layer G1_EL, and the first green anode electrode G1_AE may be connected to the first green pixel circuit G1_PD via a contact hole. The second green light emitting element ED_G2 may be electrically connected to a second green pixel circuit G2_PD. For example, the second green light emitting element ED_G2 may include a second green anode electrode G2_AE and a second green light emitting layer G2_EL, and the second green anode electrode G2_AE may be connected to the second green pixel circuit G2_PD via a contact hole.

The red light emitting element ED_R may be electrically connected to a red pixel circuit R_PD. For example, the red light emitting element ED_R may include a red anode electrode R_AE and a red light emitting layer R_EL, and the red anode electrode R_AE may be connected to the red pixel circuit R_PD via a contact hole. The blue light emitting element ED_B may be electrically connected to a blue pixel circuit B_PD. For example, the blue light emitting element ED_B may include a blue anode electrode B_AE and a blue light emitting layer B_EL, and the blue anode electrode B_AE may be connected to the blue pixel circuit B_PD via a contact hole.

Each of the sensors FX may include one light receiving element OPD and the sensor circuit SD. The light receiving element OPD may be located between the blue and red light emitting elements ED_B and ED_R in the first direction DR1 and may be located between the first and second green light emitting elements ED_G1 and ED_G2 in the second direction DR2. However, the present disclosure should not be limited thereto or thereby, and each of the sensors FX may include a plurality of light receiving elements OPD.

The sensor circuit SD may be connected to the light receiving element OPD. The sensor circuit SD may have the same length as the red and blue pixel circuits R_PD and B_PD in the second direction DR2. The sensor circuit SD may overlap one of the first and second green light emitting elements ED_G1 and ED_G2, e.g., the first green light emitting element ED_G1, when viewed in the plane.

The light receiving element OPD may include the sensing anode electrode O_AE and the photoelectric conversion layer O_RL. The sensing anode electrode O_AE may be directly connected to the sensor circuit SD via a contact hole.

Some of the sensors FX may further include a routing line RW electrically connecting the light receiving element OPD to the corresponding sensor circuit SD. The routing line RW may be electrically connected to the sensing anode electrode O_AE. As an example, the routing line RW may be provided integrally with the sensing anode electrode O_AE. The light receiving element OPD and the sensor circuit SD connected to the light receiving element OPD through the routing line RW may not overlap each other when viewed in the plane. The light receiving element OPD and the sensor circuit SD of the sensor FX that does not include the routing line RW may overlap each other when viewed in the plane.

The routing line RW and the sensing anode electrode O_AE may be located at the same layer as the anode electrodes R_AE, G1_AE, G2_AE, and B_AE. In this case, the routing line RW and the sensing anode electrode O_AE may include the same materials as the anode electrodes R_AE, G1_AE, G2_AE, and B_AE and may be formed through the same process as the anode electrodes R_AE, G1_AE, G2_AE, and B_AE.

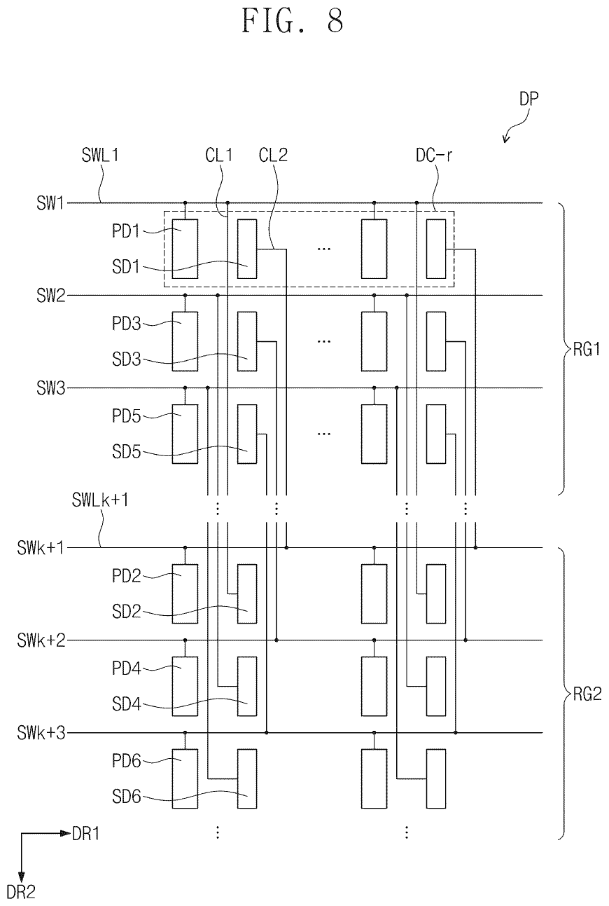

FIG. 8 is a block diagram of the pixel circuit and the sensor circuit according to some embodiments of the present disclosure.

Referring to FIG. 8, pixel circuits PD1, PD2, PD3, PD4, PD5, and PD6 may be arranged alternately with sensor circuits SD1, SD2, SD3, SD4, SD5, and SD6 in the first direction DR1, respectively. The pixel circuits PD1 to PD6 may be arranged in the second direction DR2, and the sensor circuits SD1 to SD6 may be arranged in the second direction DR2. One row in which the pixel circuits PD1 to PD6 are alternately arranged with the sensor circuits SD1 to SD6 in the first direction DR1 is referred to as a circuit row DC-r.

The pixel circuits PD1 to PD6 and the sensor circuits SD1 to SD6 may be grouped into a first circuit group RG1 and a second circuit group RG1. As an example, each of the first circuit group RG1 and the second circuit group RG2 may include k (k is an integer greater than or equal to 2) circuit rows DC-r. FIG. 8 shows three circuit rows DC-r among the k circuit rows DC-r included in each of the first circuit group RG1 and the second circuit group RG2.

The first circuit group RG1 may include a first pixel circuit PD1 and a first sensor circuit SD1 arranged in a first circuit row DC-r, a third pixel circuit PD3 and a third sensor circuit SD3 arranged in a second circuit row DC-r, and a fifth pixel circuit PD5 and a fifth sensor circuit SD5 arranged in a third circuit row DC-r. The second circuit group RG2 may include a second pixel circuit PD2 and a second sensor circuit SD2 arranged in a (k+1)th circuit row DC-r, a fourth pixel circuit PD4 and a fourth sensor circuit SD4 arranged in a (k+2)th circuit row DC-r, and a sixth pixel circuit PD6 and a sixth sensor circuit SD6 arranged in a (k+3)th circuit row DC-r.

Arrangement and connection relationships between the first and second pixel circuits PD1 and PD2 and the first and second sensor circuits SD1 and SD2 may be similar to arrangement and connection relationships between the third and fourth pixel circuits PD3 and PD4 and the third and fourth sensor circuits SD3 and SD4, and arrangement and connection relationships between the fifth and sixth pixel circuits PD5 and PD6 and the fifth and sixth sensor circuits SD5 and SD6. Hereinafter, the first pixel circuit PD1, the second pixel circuit PD2, the first sensor circuit SD1, and the second sensor circuit SD2 will be described, and descriptions of the pixel circuits PD3 to PD6 and the sensor circuits SD3 to SD6 are omitted.

The first pixel circuit PD1 and the first sensor circuit SD1 may be arranged adjacent to each other in the first direction DR1, and the second pixel circuit PD2 and the second sensor circuit SD2 may be arranged adjacent to each other in the first direction DR1. The first pixel circuit PD1 and the second pixel circuit PD2 may be spaced apart from each other in the second direction DR2, and the first sensor circuit SD1 and the second sensor circuit SD2 may be spaced apart from each other in the second direction DR2. As an example, the first pixel circuit PD1 and the second pixel circuit PD2 may be spaced apart from each other, and k−1 pixel circuits may be located between the first pixel circuit PD1 and the second pixel circuit PD2. The first sensor circuit SD1 and the second sensor circuit SD2 may be spaced apart from each other, and k−1 sensor circuits may be located between the first sensor circuit SD1 and the second sensor circuit SD2.

The first circuit group RG1 may receive write scan signals SW1, SW2, and SW3 sequentially activated, and the second circuit group RG2 may receive write scan signals SWk+1, SWk+2, and SWk+3 sequentially activated. According to some embodiments, the first pixel circuit PD1 may receive the first write scan signal SW1 through the first write scan line SWL1, and the second pixel circuit PD2 may receive the (k+1)th write scan signal SWk+1 through a (k+1)th write scan line SWLk+1. The first write scan signal SW1 may be referred to as a first scan signal, and the (k+1)th write scan signal SWk+1 may be referred to as a second scan signal.

The first sensor circuit SD1 may be connected to the (k+1)th write scan line SWLk+1 through the second connection line CL2 and may receive the (k+1)th write scan signal SWk+1. The second sensor circuit SD2 may be connected to the first write scan line SWL1 through the first connection line CL1 and may receive the first write scan signal SW1.

Accordingly, the first pixel circuit PD1 and the first sensor circuit SD1, which are arranged in the same circuit row DC-r, may receive different write scan signals from each other. As an example, the first scan signal SW1 may be applied to the second transistor T2 (refer to FIG. 4) included in the first pixel circuit PD1, and the second scan signal SWk+1 may be applied to the output transistor ST3 (refer to FIG. 4) included in the first sensor circuit SD1.

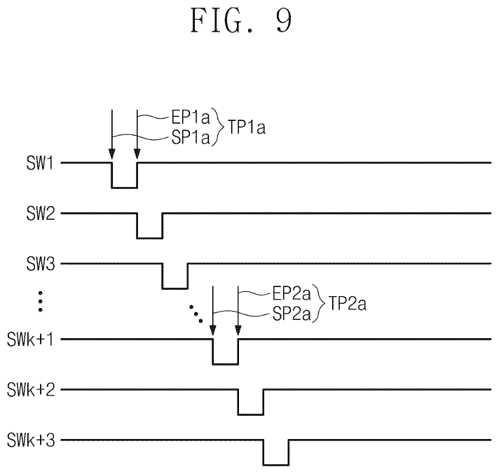

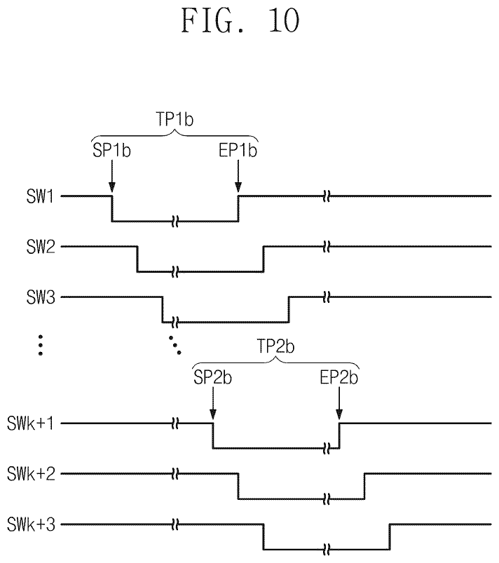

FIG. 9 is a timing diagram of scan signals shown in FIG. 8 according to some embodiments of the present disclosure. FIG. 10 is a timing diagram of scan signals shown in FIG. 8 according to some embodiments of the present disclosure.

Referring to FIGS. 8, 9, and 10, the write scan signals SW1, SW2, and SW3 applied to the first circuit group RG1 may be sequentially activated, and the write scan signals SWk+1, SWk+2, and SWk+3 applied to the second circuit group RG2 may be sequentially activated.

FIG. 9 shows the timing diagram in which the activation period of the first write scan signal SW1 does not overlap the activation period of the (k+1)th write scan signal SWk+1 as a representative example.

As an example, the activation period of the first write scan signal SW1 may be defined by a first transition time point TP1a including a first start time point SP1a and a first end time point EP1a. The activation period of the (k+1)th write scan signal SWk+1 may be defined by a second transition time point TP2a including a second start time point SP2a and a second end time point EP2a. The first transition time point TP1a may be different from the second transition time point TP2a. That is, the second start time point SP2a may be different from the first start time point SP1a and the first end time point EP1a, and the second end time point EP2a may be different from the first start time point SP1a and the first end time point EP1a. According to some embodiments, the second start time point SP2a of the (k+1)th write scan signal SWk+1 may lag behind the first end time point EP1a of the first write scan signal SW1.

FIG. 10 shows the timing diagram in which the activation period of the first write scan signal SW1 partially overlaps the activation period of the (k+1)th write scan signal SWk+1 as a representative example.

As an example, the activation period of the first write scan signal SW1 may be defined by a first transition time point TP1b including a first start time point SP1b and a first end time point EP1b. The activation period of the (k+1)th write scan signal SWk+1 may be defined by a second transition time point TP2b including a second start time point SP2b and a second end time point EP2b. The first transition time point TP1b may be different from the second transition time point TP2b. That is, the second start time point SP2b may be different from the first start time point SP1b and the first end time point EP1b, and the second end time point EP2b may be different from the first start time point SP1b and the first end time point EP1b. According to some embodiments, the second start time point SP2b of the (k+1)th write scan signal SWk+1 may precede the first end time point EP1b of the first write scan signal SW1.

As described above, the sensor circuits SD1 to SD6 are driven using the write scan signals SW1 to SWk+3. However, the present disclosure is not limited thereto. The sensor circuits SD1 to SD6 may be driven using one of the j-th compensation scan signal SCj (refer to FIG. 4), the j-th initialization scan signal SIj (refer to FIG. 4), and the j-th black scan signal SBj (refer to FIG. 4). Even in this case, the sensor circuits may operate in a manner similar to the case of receiving the write scan signals SW1 to SWj+1 may be applied.

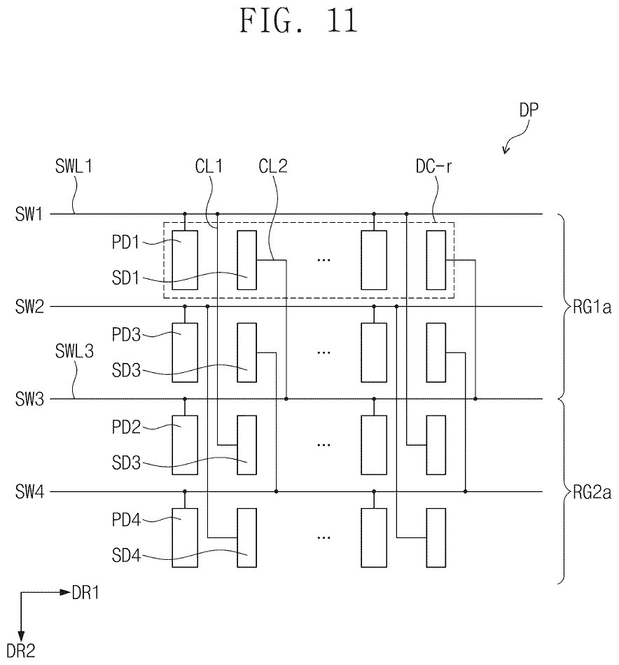

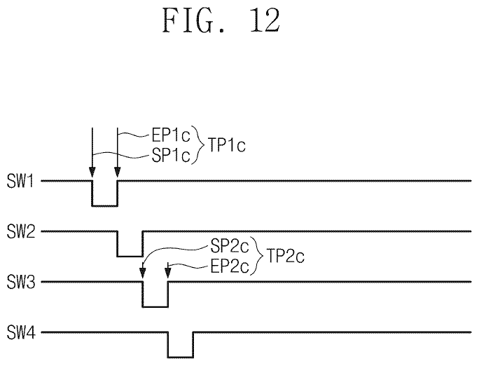

FIG. 11 is a block diagram of a pixel circuit and a sensor circuit according to some embodiments of the present disclosure. FIG. 12 is a timing diagram of scan signals shown in FIG. 11.

FIG. 11 shows a case where each of a first circuit group RG1a and a second circuit group RG2a includes two circuit rows DC-r, i.e., a case where k is 2, as a representative example.

Referring to FIGS. 11 and 12, pixel circuits PD1, PD2, PD3, and PD4 and sensor circuits SD1, SD2, SD3, and SD4 may be grouped into the first circuit group RG1a and the second circuit group RG2a. The first circuit group RG1a may include a first pixel circuit PD1 and a first sensor circuit SD1 arranged in a first circuit row DC-r and a third pixel circuit PD3 and a third sensor circuit SD3 arranged in a second circuit row DC-r. The second circuit group RG2a may include a second pixel circuit PD2 and a second sensor circuit SD2 arranged in a third circuit row DC-r and a fourth pixel circuit PD4 and a fourth sensor circuit SD4 arranged in a fourth circuit row DC-r.

The first circuit group RG1a may receive write scan signals SW1 and SW2 sequentially activated, and the second circuit group RG2a may receive write scan signals SW3 and SW4 sequentially activated. According to some embodiments, the first pixel circuit PD1 may receive a first write scan signal SW1 through a first write scan line SWL1, and the second pixel circuit PD2 may receive a third write scan signal SW3 through a third write scan line SWL3.

The first sensor circuit SD1 may be connected to a third write scan line SWL3 through a second connection line CL2 and may receive a third write scan signal SW3, and the second sensor circuit SD2 may be connected to a first write scan line SWL1 through a first connection line CL1 and may receive the first write scan signal SW1.

The write scan signals SW1 to SW4 applied to the first circuit group RG1a and the second circuit group RG2a may be sequentially activated.

As an example, an activation period of the first write scan signal SW1 may be defined by a first transition time point TP1c including a first start time point SP1c and a first end time point EP1c. An activation period of the third write scan signal SW3 may be defined by a second transition time point TP2c including a second start time point SP2c and a second end time point EP2c. The first transition time point TP1c may be different from the second transition time point TP2c. That is, the second start time point SP2c may be different from the first start time point SP1c and the first end time point EP1c, and the second end time point EP2c may be different from the first start time point SP1c and the first end time point EP1c.

According to the present disclosure, the first sensor circuit SD1 arranged in the same circuit row DC-r as the first pixel circuit PD1 receiving the first write scan signal SW1 may receive the third write scan signal SW3 different from the first write scan signal SW1. According to some embodiments, the first transition time point TP1c of the first write scan signal SW1 may be different from the second transition time point TP2c of the third write scan signal SW3. Accordingly, when a voltage level of the first write scan signal SW1 is changed at the first transition time point TP1c, the third write scan signal SW3 may not be affected by the first write scan signal SW1 even though the first pixel circuit PD1 and the first sensor circuit SD1 are adjacent to each other. Accordingly, the sensing performance of the electronic device may increase.

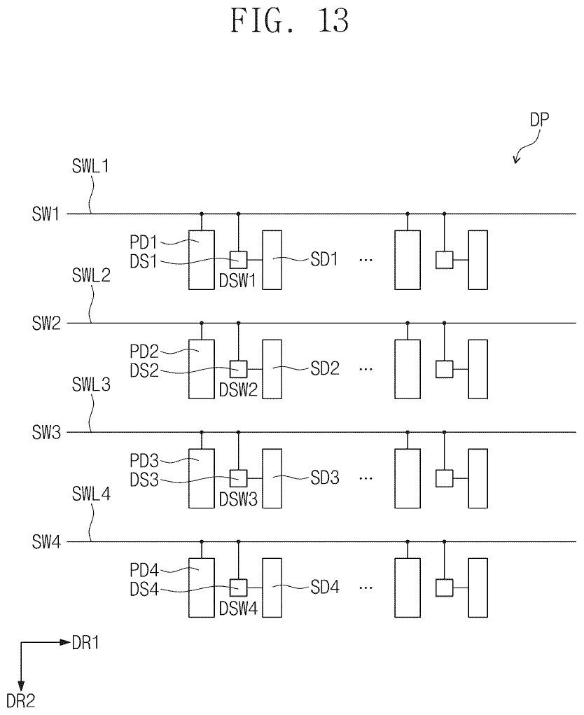

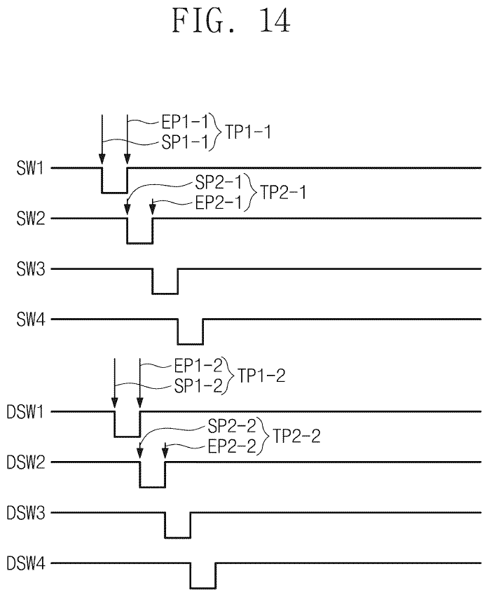

FIG. 13 is a block diagram of a pixel circuit and a sensor circuit according to some embodiments of the present disclosure. FIG. 14 is a timing diagram of scan signals shown in FIG. 13.

Referring to FIGS. 13 and 14, pixel circuits PD1, PD2, PD3, and PD4 may be alternately arranged with sensor circuits SD1, SD2, SD3, and SD4 in the first direction DR1, respectively. The pixel circuits PD1 to PD4 may be arranged in the second direction DR2, and the sensor circuits SD1 to SD4 may be arranged in the second direction DR2. As an example, the display panel DP may further include signal delay parts DS1, DS2, DS3, and DS4.

A first pixel circuit PD1, a first sensor circuit SD1, and a first signal delay part DS1 may be arranged in a first circuit row of the display panel DP. The first pixel circuit PD1 may receive a first write scan signal SW1. The first signal delay part DS1 may be located between a first write scan line SWL1 and the first sensor circuit SD1. Accordingly, the first signal delay part DS1 may receive the first write scan signal SW1 from the first write scan line SWL1, may delay the first write scan signal SW1 for a selected time, and then may output a first delay scan signal DSW1. The first sensor circuit SD1 may receive the first delay scan signal DSW1 from the first signal delay part DS1.

Accordingly, the first pixel circuit PD1 and the first sensor circuit SD1, which are arranged in the same circuit row, may receive different write scan signals from each other. As an example, the first scan signal SW1 may be applied to the second transistor T2 (refer to FIG. 4) included in the first pixel circuit PD1, and the first delay scan signal DSW1 may be applied to the output transistor ST3 (refer to FIG. 4) included in the first sensor circuit SD1.

A second pixel circuit PD2, a second sensor circuit SD2, and a second signal delay part DS2 may be arranged in a second circuit row of the display panel DP. The second pixel circuit PD2 may receive a second write scan signal SW2. The second signal delay part DS2 may be located between a second write scan line SWL2 and the second sensor circuit SD2. Accordingly, the second signal delay part DS2 may receive the second write scan signal SW2 from the second write scan line SWL2, may delay the second write scan signal SW2 for a selected time, and then may output a second delay scan signal DSW2. The second sensor circuit SD2 may receive the second delay scan signal DSW2 from the second signal delay part DS2.

As an example, the signal delay parts DS1 to DS4 may delay signals using elements such as a resistor and a capacitor. According to some embodiments, the signal delay parts DS1 to DS4 may delay signals using a buffer implemented by an element such as a complementary metal-oxide-semiconductor (CMOS). However, the present disclosure should not be limited thereto or thereby, and various elements and circuit configurations may be used to delay signals for a selected time. According to some embodiments, the sensor circuits SD1 to SD4 may be configured to receive the write scan signals SW1 to SW4 as delay scan signals DSW1 to DSW4 after a selected time without using a separate component.

As shown in FIG. 13, each of the signal delay parts DS1 to DS4 is located between a corresponding write scan line among the write scan lines SWL1 to SWL4 and a corresponding sensor circuit among the sensor circuits SD1 to SD4, however, the arrangement of the signal delay parts DS1 to DS4 should not be limited thereto or thereby.

The first to fourth write scan signals SW1 to SW4 may be sequentially activated, and the first to fourth delay scan signals DSW1 to DSW4 may be sequentially activated after being delayed for a selected time respectively from the first to fourth write scan signals SW1 to SW4.

As an example, an activation period of the first write scan signal SW1 may be defined by a first-first transition time point TP1-1 including a first-first start time point SP1-1 and a first-first end time point EP1-1, and an activation period of the first delay scan signal DSW1 may be defined by a first-second transition time point TP1-2 including a first-second start time point SP1-2 and a first-second end time point EP1-2. The first-first transition time point TP1-1 may be different from the first-second transition time point TP1-2. That is, the first-second start time point SP1-2 may be different from the first-first start time point SP1-1 and the first-first end time point EP1-1, and the first-second end time point EP1-2 may be different from the first-first start time point SP1-1 and the first-first end time point EP1-1.

An activation period of the second write scan signal SW2 may be defined by a second-first transition time point TP2-1 including a second-first start time point SP2-1 and a second-first end time point EP2-1, and an activation period of the second delay scan signal DSW2 may be defined by a second-second transition time point TP2-2 including a second-second start time point SP2-2 and a second-second end time point EP2-2. The second-first transition time point TP2-1 may be different from the second-second transition time point TP2-2. That is, the second-second start time point SP2-2 may be different from the second-first start time point SP2-1 and the second-first end time point EP2-1, and the second-second end time point EP2-2 may be different from the second-first start time point SP2-1 and the second-first end time point EP2-1.

As an example, the first-second transition time point TP1-2 may be different from the second-first transition time point TP2-1. That is, the second-first start time point SP2-1 may be different from the first-second start time point SP1-2 and the first-second end time point EP1-2, and the second-first end time point EP2-1 may be different from the first-second start time point SP1-2 and the first-second end time point EP1-2.

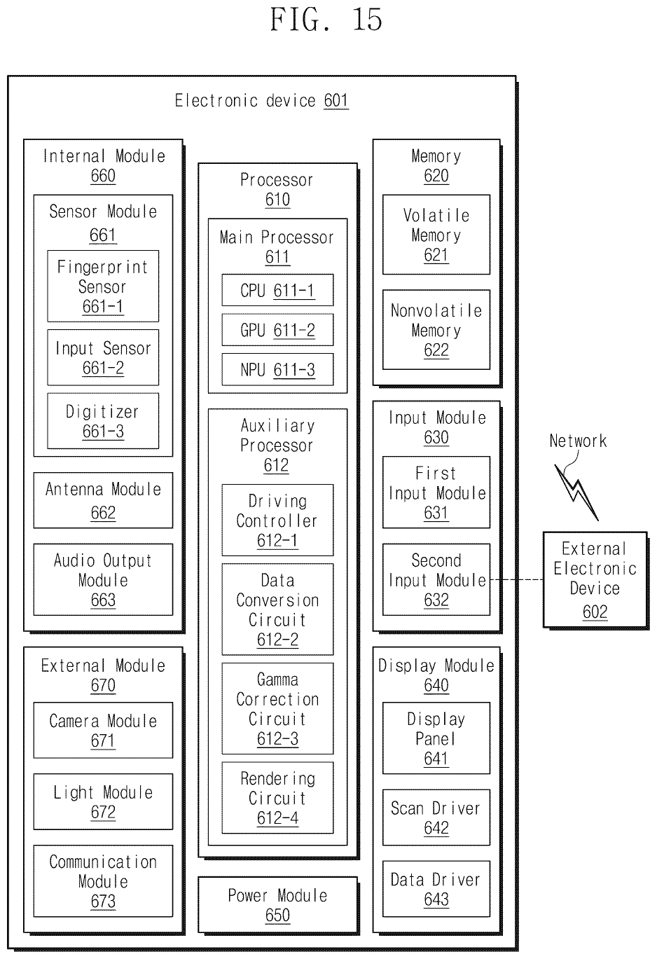

FIG. 15 is a block diagram of an electronic device according to some embodiments of the present disclosure.

Referring to FIG. 15, the electronic device 601 may output various pieces of information through a display module 640 within an operating system. When a processor 610 executes an application stored in a memory 620, the display module 640 may provide application information to a user through a display panel 641.

The processor 610 may obtain an external input through an input module 630 or a sensor module 661 and execute an application corresponding to the external input. For example, when the user selects a camera icon displayed on the display panel 641, the processor 610 may obtain a user input through an input sensor 661-2 and activate a camera module 671. The processor 610 may transmit image data corresponding to a captured image obtained through the camera module 671 to the display module 640. The display module 640 may display an image corresponding to the captured image through the display panel 641.

According to some embodiments, when personal information authentication is executed in the display module 640, a fingerprint sensor 661-1 may acquire input fingerprint information as input data. The processor 610 may compare the input data acquired through the fingerprint sensor 661-1 with authentication data stored in the memory 620 and execute an application according to the comparison result. The display module 640 may display information executed according to a logic of the application through the display panel 641.

According to some embodiments, when a music streaming icon displayed on the display module 640 is selected, the processor 610 may obtain a user input through the input sensor 661-2 and activate a music streaming application stored in the memory 620. When a music playback command is input in the music streaming application, the processor 610 may activate an audio output module 663 to provide audio information corresponding to the music playback command to the user.

In the above, the operation of the electronic device 601 is briefly described. Hereinafter, components of the electronic device 601 will be described in more detail. Some of the components of the electronic device 601 described below may be integrated and provided as a single component, or one component may be provided after being separated into two or more components.

Referring to FIG. 15, the electronic device 601 may communicate with an external electronic device 602 through a network (for example, a short-range wireless communication network or a long-range wireless communication network). According to some embodiments, the electronic device 601 may include the processor 610, the memory 620, the input module 630, the display module 640, a power module 650, an internal module 660, and an external module 670. According to some embodiments, in the electronic device 601, at least one of the above-described components may be omitted or one or more other components may be added. According to some embodiments, some of the components (for example, a sensor module 661, an antenna module 662, or an audio output module 663) may be integrated into another component (for example, the display module 640).

The processor 610 may execute software to control at least one other component (for example, a hardware or software component) of the electronic device 601 connected to the processor 610 and may perform various data processing or computational operations. According to some embodiments, as at least a part of the data processing or computational operations, the processor 610 may store commands or data received from other components (for example, the input module 630, the sensor module 661, or a communication module 673) in a volatile memory 621, may process the commands or data stored in the volatile memory 621, and may store result data in a nonvolatile memory 622.

The processor 610 may include a main processor 611 and an auxiliary processor 612. The main processor 611 may include one or both of a central processing unit (CPU) 611-1 and an application processor (AP). The main processor 611 may further include any one or more of a graphics processing unit (GPU) 611-2, a communication processor (CP), and an image signal processor (ISP). The main processor 611 may further include a neural processing unit (NPU) 611-3. The NPU is a processor specialized in processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of two or more of the above, but is not limited to the above-described example. In addition to or as an alternative to a hardware structure, the artificial intelligence model may include a software structure. At least two of the above-described processing units and processors may be implemented as a single integrated component (for example, a single chip) or as separate components (for example, a plurality of chips).

The auxiliary processor 612 may include a driving controller 612-1. The driving controller 612-1 may include an interface conversion circuit and a timing control circuit. The driving controller 612-1 may receive an image signal from the main processor 611, convert a data format of the image signal to correspond to an interface specification with the display module 640, and output image data. The driving controller 612-1 may output various control signals required for driving the display module 640. The configuration of the driving controller 612-1 may be similar to that of the driving controller 100 shown in FIG. 3, and thus, detailed descriptions of the driving controller 612-1 are omitted.

The auxiliary processor 612 may further include a data conversion circuit 612-2, a gamma correction circuit 612-3, a rendering circuit 612-4, and the like. The data conversion circuit 612-2 may receive the image data from the driving controller 612-1, compensate for the image data to display an image with a desired luminance based on characteristics of the electronic device 601, user settings, or the like, or convert the image data to reduce power consumption or to compensate for image retention. The gamma correction circuit 612-3 may convert the image data, a gamma reference voltage, or the like so that the image displayed on the electronic device 601 has a desired gamma characteristic. The rendering circuit 612-4 may receive the image data from the driving controller 612-1 and render the image data taking into account a pixel arrangement or the like of the display panel 641 applied to the electronic device 601. At least one of the data conversion circuit 612-2, the gamma correction circuit 612-3, or the rendering circuit 612-4 may be integrated into another component (for example, the main processor 611 or the driving controller 612-1). At least one of the data conversion circuit 612-2, the gamma correction circuit 612-3, or the rendering circuit 612-4 may be integrated into a data driver 643, which is described in more detail later.

The memory 620 may store various data used by at least one component (for example, the processor 610 or the sensor module 661) of the electronic device 601 and input or output data related to corresponding commands. The memory 620 may include at least one of the volatile memory 621 or the nonvolatile memory 622.

The input module 630 may receive commands or data to be used by a component (for example, the processor 610, the sensor module 661, or the audio output module 663) of the electronic device 601 from an external source (for example, the user or the external electronic device 602) of the electronic device 601.

The input module 630 may include a first input module 631 receiving commands or data from the user and a second input module 632 receiving commands or data from the external electronic device 602. The first input module 631 may include a microphone, a mouse, a keyboard, a key (for example, a button), or a pen (for example, a passive pen or an active pen). The second input module 632 may support a designated protocol that enables connection to the external electronic device 602 via a wired or wireless connection. According to some embodiments, the second input module 632 may include a high definition multimedia interface (HDMI), a universal serial bus (USB) interface, an SD card interface, or an audio interface. The second input module 632 may include a connector capable of physically connecting to the external electronic device 602, for example, an HDMI connector, a USB connector, an SD card connector, or an audio connector (for example, a headphone connector).

The display module 640 may provide visual information to the user. The display module 640 may include the display panel 641, a scan driver 642, and the data driver 643. The display module 640 may further include a window, a chassis, and a bracket to protect the display panel 641. The display module 640 may further include an emission driver, a voltage generator, and the like. The voltage generator may output various voltages, e.g., the first and second driving voltages ELVDD and ELVSS (refer to FIG. 3A), required for driving the display panel 641. The configurations of the display panel 641, the scan driver 642, the data driver 643, and the voltage generator may be similar (or substantially similar) to those of the display panel DP, the scan driver 300, the data driver 200 and voltage generator 400 shown in FIG. 3, and thus, detailed descriptions of the display panel 641, the scan driver 642, the data driver 643, and the voltage generator are omitted.

The power module 650 may supply power to components of the electronic device 601. The power module 650 may include a battery that charges a power voltage. The battery may include a non-rechargeable primary cell, a rechargeable secondary cell, or fuel cell. The power module 650 may include a power management integrated circuit (PMIC). The PMIC may supply optimized power to each of the above-described modules and modules described later. The power module 650 may include a wireless power transmission/reception member electrically connected to the battery. The wireless power transmission/reception member may include a plurality of antenna radiators of a coil form.

The electronic device 601 may further include the internal module 660 and the external module 670. The internal module 660 may include the sensor module 661, the antenna module 662, and the audio output module 663. The external module 670 may include the camera module 671, a light module 672, and the communication module 673.

The sensor module 661 may sense an input by a body of the user or an input by a pen of the first input module 631 and may generate an electrical signal or a data value corresponding to the input. The sensor module 661 may include at least one of the fingerprint sensor 661-1, the input sensor 661-2, or a digitizer 661-3.

The fingerprint sensor 661-1 may generate a data value corresponding to a fingerprint of the user. The fingerprint sensor 661-1 may include any one of an optical type fingerprint sensor or a capacitive type fingerprint sensor.

The input sensor 661-2 may generate a data value corresponding to coordinate information of the input by the body of the user or the input by the pen. The input sensor 661-2 may generate the data value based on the change in capacitance caused by the input. The input sensor 661-2 may sense an input by the passive pen or may transmit/receive data to and from the active pen.

The input sensor 661-2 may measure a biometric signal such as blood pressure, hydration levels, or body fat. For example, when the user touches a part of their body to a sensor layer or a sensing panel and remains still for a certain period, the input sensor 661-2 may sense the biometric signal based on changes in an electric field caused by the body part and output information desired by the user to the display module 640.

The digitizer 661-3 may generate a data value corresponding to coordinate information of the input by the pen. The digitizer 661-3 may generate the data value based on changes in an electromagnetic field caused by the input. The digitizer 661-3 may sense the input by the passive pen or may transmit/receive data to and from the active pen.

At least one of the fingerprint sensor 661-1, the input sensor 661-2, or the digitizer 661-3 may be implemented as a sensor layer formed on the display panel 641 through a continuous process. The fingerprint sensor 661-1, the input sensor 661-2, and the digitizer 661-3 may be located above the display panel 641, or any one of the fingerprint sensor 661-1, the input sensor 661-2, and the digitizer 661-3, for example, the digitizer 661-3 may be located below the display panel 641.

At least two of the fingerprint sensor 661-1, the input sensor 661-2, and the digitizer 661-3 may be integrated into a single sensing panel through the same process. When at least two of the fingerprint sensor 661-1, the input sensor 661-2, and the digitizer 661-3 are integrated into one sensing panel, the sensing panel may be located between the display panel 641 and the window located above the display panel 641. According to some embodiments, the sensing panel may be located on the window, and a position of the sensing panel should not be particularly limited.

At least one of the fingerprint sensor 661-1, the input sensor 661-2, or the digitizer 661-3 may be embedded in the display panel 641. That is, at least one of the fingerprint sensor 661-1, the input sensor 661-2, or the digitizer 661-3 may be simultaneously (or concurrently) formed through a process of forming elements (for example, a light emitting element, a transistor, and the like) included in the display panel 641.

In addition, the sensor module 661 may generate an electrical signal or a data value corresponding to an internal state or an external state of the electronic device 601. The sensor module 661 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 662 may include one or more antennas to transmit a signal or power to an external source or to receive a signal or power from an external source. According to some embodiments, the communication module 673 may transmit a signal to an external electronic device or may receive a signal from an external electronic device through an antenna suitable for a communication method. An antenna pattern of the antenna module 662 may be integrated into one component (for example, the display panel 641) of the display module 640 or the input sensor 661-2.

The audio output module 663 is a device to output an audio signal to an outside of the electronic device 601 and, for example, may include a speaker used for general purposes such as multimedia playback or voice recording playback and a receiver used exclusively to receive a phone call. According to some embodiments, the receiver may be formed integrally with or separately from the speaker. An audio output pattern of the audio output module 663 may be integrated into the display module 640.

The camera module 671 may capture a still image and a video. According to some embodiments, the camera module 671 may include one or more lenses, an image sensor, or an image signal processor. The camera module 671 may further include an infrared camera capable of detecting presence or absence of the user, a position of the user, a gaze of the user, and the like.

The light module 672 may provide light. The light module 672 may include a light emitting diode or a xenon lamp. The light module 672 may operate in conjunction with the camera module 671 or may operate independently.

The communication module 673 may support the establishment of a wired or wireless communication channel between the electronic device 601 and the external electronic device 602 and the communication through the established communication channel. The communication module 673 may include one or both of a wireless communication module, such as a cellular communication module, a short-range wireless communication module, or a global navigation satellite system (GNSS) communication module, and a wired communication module, such as a local area network (LAN) communication module or a power line communication module. The communication module 673 may communicate with the external electronic device 602 through a short-range communication network such as Bluetooth, WiFi direct, or infrared data association (IrDA), or a long-range communication network such as a cellular network, the Internet, or a computer network (for example, LAN or WAN). The various types of communication modules 673 described above may be implemented as a single chip or as separate chips.

The input module 630, the sensor module 661, the camera module 671, and the like may be used in conjunction with the processor 610 to control an operation of the display module 640.

The processor 610 may output commands or data to the display module 640, the audio output module 663, the camera module 671, or the light module 672 based on input data received from the input module 630. For instance, the processor 610 may generate image data in response to the input data applied through the mouse, the active pen, or the like and output the image data to the display module 640, or may generate command data in response to the input data and output the command data to the camera module 671 or the light module 672. When no input data is received from the input module 630 for a certain period of time, the processor 610 may switch the operation mode of the electronic device 601 to a low power mode or a sleep mode to reduce power consumed in the electronic device 601.

The processor 610 may output commands or data to the display module 640, the audio output module 663, the camera module 671, or the light module 672 based on sensing data received from the sensor module 661. For instance, the processor 610 may compare authentication data applied by the fingerprint sensor 661-1 with authentication data stored in the memory 620 and then execute an application according to a comparison result. The processor 610 may execute the command based on sensing data sensed by the input sensor 661-2 or the digitizer 661-3 or may output image data corresponding to the sensing data to the display module 640. When the sensor module 661 includes a temperature sensor, the processor 610 may receive temperature data measured by the sensor module 661 and further perform luminance correction or the like on the image data based on the temperature data.

The processor 610 may receive detected data regarding the presence or absence of the user, the position of the user, the gaze of the user, and the like, from the camera module 671. The processor 610 may further perform luminance correction or the like on the image data based on the detected data. For instance, when the processor 610 determines the presence or absence of the user through an input from the camera module 671, the processor 610 may output image data whose luminance is corrected through the data conversion circuit 612-2 or the gamma correction circuit 612-3 to the display module 640.

Among the above-described components, some components may be connected to each other through a communication method for peripheral devices, for example, a bus, general purpose input/output (GPIO), a serial peripheral interface (SPI), a mobile industry processor interface (MIPI), or an ultra-path interconnect (UPI) link to exchange a signal (for example, commands or data) with each other. The processor 610 may communicate with the display module 640 through a mutually agreed interface, for example, any one of the above-described communication methods, and the communication method should not be limited to the above-described communication methods.

The electronic device 601 according to various embodiments of the present disclosure may be applied to various types of devices. The electronic device 601 may include, for example, at least one of a portable communication device (e.g., a smartphone), a computer device, a portable multimedia device, a portable medical device, a camera, a wearable device, or a home appliance device. The electronic device 601 according to various embodiments of the present disclosure should not be limited to the above-described devices.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims, and their equivalents.

What is claimed is:

1. A display device comprising:
a base layer;
a circuit layer on the base layer; and
an element layer on the circuit layer and comprising light emitting elements and light receiving elements arranged in a display area, wherein the circuit layer comprises pixel circuits connected to the light emitting elements and sensor circuits connected to the light receiving elements, each of the pixel circuits and the sensor circuits are configured to receive one of scan signals sequentially activated, and a first transition time point of a first scan signal applied to a first pixel circuit arranged in a first circuit row among the pixel circuits is different from a second transition time point of a second scan signal applied to a first sensor circuit arranged in the first circuit row among the sensor circuits.

2. The display device of claim 1, wherein a second pixel circuit in a (k+1)th circuit row among the pixel circuits is configured to receive the second scan signal, and a second sensor circuit arranged in the (k+1)th circuit row among the sensor circuits is configured to receive the first scan signal, and k is an integer greater than or equal to 2.

3. The display device of claim 2, further comprising pixel circuits arranged in k−1 circuit rows between the first pixel circuit and the second pixel circuit.

4. The display device of claim 2, wherein the first transition time point of the first scan signal comprises a first start time point and a first end time point, the second transition time point of the second scan signal comprises a second start time point and a second end time point, the second start time point is different from the first start time point and the first end time point, and the second end time point is different from the first start time point and the first end time point.

5. The display device of claim 4, wherein an activation period of the first scan signal does not overlap an activation period of the second scan signal.

6. The display device of claim 4, wherein an activation period of the first scan signal partially overlaps an activation period of the second scan signal.

7. The display device of claim 2, wherein each of the pixel circuits comprises:
a driving transistor connected between a corresponding light emitting element among the light emitting elements and a first power line; and
a switching transistor connected to the driving transistor and configured to receive a data voltage, and
the switching transistor of the first pixel circuit is configured to receive the first scan signal and the switching transistor of the second pixel circuit is configured to receive the second scan signal.

8. The display device of claim 2, wherein each of the sensor circuits comprises:
a reset transistor connected between a corresponding light receiving element among the light receiving elements and a reset voltage line;
an amplification transistor connected to the reset transistor and configured to receive a sensing driving voltage; and
an output transistor connected between the amplification transistor and a read-out line, and
the output transistor of the first sensor circuit is configured to receive the second scan signal and the output transistor of the second first sensor circuit is configured to receive the first scan signal.

9. A display device comprising:
a base layer;
a circuit layer on the base layer; and
an element layer on the circuit layer and comprising light emitting elements and light receiving elements, which are arranged in a display area, wherein the circuit layer comprises pixel circuits connected to the light emitting elements and sensor circuits connected to the light receiving elements, each of the pixel circuits and the sensor circuits is configured to receive one of scan signals sequentially activated, a first scan signal is applied to a first pixel circuit arranged in a first circuit row among the pixel circuits, a first delay scan signal delayed from the first scan signal is applied to a first sensor circuit arranged in the first circuit row among the sensor circuits, and a transition time point of the first scan signal is different from a transition time point of the first delay scan signal.

10. The display device of claim 9, wherein an activation period of the first scan signal partially overlaps an activation period of the first delay scan signal.

11. The display device of claim 9, wherein the transition time point of the first scan signal comprises a first start time point and a first end time point, the transition time point of the first delay scan signal comprises a second start time point and a second end time point, the second start time point is different from the first start time point and the first end time point, and the second end time point is different from the first start time point and the first end time point.

12. The display device of claim 9, further comprises a signal delay part configured to receive the first scan signal and to output the first delay scan signal to the first sensor circuit.

13. The display device of claim 9, wherein a second pixel circuit arranged in a second circuit row among the pixel circuits is configured to receive a second scan signal, a second sensor circuit arranged in the second circuit row among the sensor circuits is configured to receive a second delay scan signal delayed from the second scan signal, and a transition time point of the second scan signal is different from a transition time point of the second delay scan signal.

14. The display device of claim 15, wherein the transition time point of the first delay scan signal is different from the transition time point of the second scan signal.

15. The display device of claim 13, wherein each of the pixel circuits comprises:
a driving transistor connected between a corresponding light emitting element among the light emitting elements and a first power line; and
a switching transistor connected to the driving transistor and configured to receive a data voltage, and
the switching transistor of the first pixel circuit is configured to receive the first scan signal and the switching transistor of the second pixel circuit is configured to receive the second scan signal.

16. The display device of claim 13, wherein each of the sensor circuits comprises:
a reset transistor connected between a corresponding light receiving element among the light receiving elements and a reset voltage line;
an amplification transistor connected to the reset transistor and configured to receive a sensing driving voltage; and
an output transistor connected between the amplification transistor and a read-out line, and
the output transistor of the first sensor circuit is configured to receive the first delay scan signal and the output transistor of the second first sensor circuit is configured to receive the second delay scan signal.

17. An electronic device comprising:
a display panel comprising pixels and sensors;
a data driver configured to apply a data voltage to the pixels; and
a scan driver configured to apply scan signals to the pixels and the sensors, wherein the pixels comprise light emitting elements and pixel circuits connected to the light emitting elements, the sensors comprise light receiving elements and sensor circuits connected to the light receiving elements, and a first transition time point of a first scan signal applied to a first pixel circuit arranged in a first circuit row among the pixel circuits is different from a second transition time point of a second scan signal applied to a first sensor circuit arranged in the first circuit row among the sensor circuits.

18. The electronic device of claim 17, wherein a second pixel circuit arranged in a (k+1)th circuit row among the pixel circuits is configured to receive the second scan signal, a second sensor circuit arranged in the (k+1)th circuit row among the sensor circuits is configured to receive the first scan signal, and k is an integer greater than or equal to 2.

19. The electronic device of claim 17, wherein each of the pixel circuits comprises:
a driving transistor connected between a corresponding light emitting element among the light emitting elements and a first power line; and
a switching transistor connected to the driving transistor and configured to receive the data voltage and,
the switching transistor of the first pixel circuit is configured to receive the first scan signal and the switching transistor of the second pixel circuit is configured to receive the second scan signal.

20. The electronic device of claim 17, wherein each of the sensor circuits comprises:
a reset transistor connected between a corresponding light receiving element among the light receiving elements and a reset voltage line;
an amplification transistor connected to the reset transistor and configured to receive a sensing driving voltage; and
an output transistor connected between the amplification transistor and a read-out line, and
the output transistor of the first sensor circuit is configured to receive the second scan signal and the output transistor of the second first sensor circuit is configured to receive the first scan signal.
